(19) United States
(12) Patent Application Publication
(10) Pub. No.: US 2024/0312891 A1
(43) Pub. Date: Sep. 19, 2024

(54) SEMICONDUCTOR STRUCTURE AND METHOD FOR MANUFACTURING A SEMICONDUCTOR STRUCTURE

(71) Applicant: SERIPHY TECHNOLOGY CORPORATION, HSINCHU COUNTY (TW)

(72) Inventors: TZU-WEI CHIU, HSINCHU COUNTY (TW); CHUN-WEI CHANG, TAIPEI CITY (TW); WEI-CHIH CHEN, TAOYUAN CITY (TW); CHE-YEN HUANG, HSINCHU COUNTY (TW)

(21) Appl. No.: 18/466,744

(22) Filed: Sep. 13, 2023

Related U.S. Application Data
(60) Provisional application No. 63/490,767, filed on Mar. 16, 2023.

(51) Int. Cl. H01L 23/498; H01L 21/683; H01L 23/00; H01L 23/31

(52) U.S. Cl. CPC H01L 23/49838; H01L 21/6836; H01L 23/3171; H01L 23/49816; H01L 23/49822; H01L 24/05; H01L 24/97; H01L 2224/05023; H01L 2224/05073; H01L 2224/97; H01L 2924/1437; H01L 2924/15311; H01L 2924/182; H10B 80/00

(57) ABSTRACT

A semiconductor structure includes a plurality of dies over a redistribution layer (RDL). A first die comprises: a first substrate; a first (RDL), disposed over a front surface of the first substrate; and a first back-side through via (BSTV), extending from a back surface of the first substrate toward the front surface of the first substrate. A second die, adjacent to the first die and separated from the first die by a molding material, comprises: a second substrate; a second RDL, disposed over a front surface of the second substrate; and a second BSTV, extending from a back surface of the second substrate toward the front surface of the second substrate. The RDL continuously covers the back surfaces of the first and second substrates, and electrically connects the first RDL to the second RDL via the first and second BSTVs. A method of manufacturing the semiconductor structure is also provided.

### CROSS REFERENCE

This application claims the benefit of prior-filed U.S. provisional application No. 63/490,767, filed on Mar. 16, 2023, which is incorporated by reference in its entirety.

### TECHNICAL FIELD

The present disclosure relates to a semiconductor structure, and more particularly, to a semiconductor structure having a die-stacking structure.

### DISCUSSION OF THE BACKGROUND

As artificial intelligence (AI) models are applied to more and more fields, demand for suitable hardware having greater computational capability increases. Since the AI models usually require large amounts of parallel computing, most computational hardware used therein includes multiple cores, the use of which requires large circuit areas. Furthermore, to improve computational efficiency, data sharing and/or data switching among different cores is also desired. However, to enable the data sharing and/or the data switching, connections between the cores can be complicated and require even greater area. Therefore, providing a semiconductor structure that can facilitate greater computational capability within a smaller area or thickness has become an issue to be solved.

### SUMMARY

One embodiment of the present disclosure discloses a semiconductor structure. The semiconductor structure includes a first die, comprising: a first substrate, having a first active area at a front surface of the first substrate; a first redistribution layer (RDL), disposed over the front surface of the first substrate; and a first back-side through via (BSTV), extending from a back surface of the first substrate toward the front surface of the first substrate. The semiconductor structure further includes a second die, disposed adjacent to the first die, and separated from the first die by a molding material, wherein the second die comprises: a second substrate, having a second active area at a front surface of the second substrate; a second RDL, disposed over the front surface of the second substrate; and a second BSTV, extending from a back surface of the second substrate toward the front surface of the second substrate. The semiconductor structure further includes a third RDL, continuously disposed over the back surfaces of the first substrate and the second substrate, and electrically connecting to the first RDL through the first BSTV and to the second RDL through the second BSTV.

Another embodiment of the present disclosure discloses a method for manufacturing a semiconductor structure. The method includes several operations: forming an etch stop layer in a first substrate proximal to a front surface of the first substrate; forming an active area at the front surface of the first substrate over the etch stop layer; forming a first redistribution layer (RDL) over the front surface of the first substrate; bonding the first RDL to a second substrate; reducing a thickness of the first substrate from a back surface of the first substrate until an exposure of the etch stop layer occurs; forming a back-side through via (BSTV) in the first substrate from the back surface of the first substrate; and forming a second RDL over the back surface of the first substrate, wherein the second RDL is electrically connected to the first RDL through the BSTV.

The semiconductor structure and the method for manufacturing the semiconductor structure adopts a die-stacking structure to accommodate multiple core dies within one package. The die-stacking structure not only allows greater computational capability within a smaller area, but also enables faster data sharing and/or data switching.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures.

FIG. 1 is a schematic cross-sectional view of a semiconductor structure 1 in accordance with some embodiments of the present disclosure.

FIG. 2 is a schematic cross-sectional diagram of the semiconductor structure 1 showing signal transmission indicated by different arrows in accordance with some embodiments of the present disclosure.

FIG. 3 is a schematic top view of the semiconductor structure 1 showing signal transmission indicated by different arrows in accordance with some embodiments of the present disclosure.

FIG. 4 is a schematic cross-sectional view of a semiconductor structure 2 in accordance with some embodiments of the present disclosure.

FIG. 5 is a schematic cross-sectional diagram of the semiconductor structure 2 showing signal transmission indicated by different arrows in accordance with some embodiments of the present disclosure.

FIG. 6 is a schematic cross-sectional view of a semiconductor structure 3 in accordance with some embodiments of the present disclosure.

FIG. 7 is a schematic cross-sectional diagram of the semiconductor structure 3 showing signal transmission indicated by different arrows in accordance with some embodiments of the present disclosure.

FIGS. 8 to 15 are schematic diagrams of a semiconductor structure at different stages of a manufacturing method in accordance with some embodiments of the present disclosure.

FIG. 16 is a schematic cross-sectional diagram of a semiconductor structure at a stage of a manufacturing method in accordance with some embodiments of the present disclosure.

FIG. 17 is a schematic cross-sectional diagram of a semiconductor structure at a stage of a manufacturing method in accordance with some embodiments of the present disclosure.

FIGS. 18 to 26 are schematic diagrams of a semiconductor structure at different stages of a manufacturing method in accordance with some embodiments of the present disclosure.

FIG. 27 is a schematic top view of a semiconductor structure placed on a dicing tape in accordance with some embodiments of the present disclosure.

FIG. 28 is a schematic cross-sectional view of a semiconductor structure in accordance with some embodiments of the present disclosure.

FIG. 29 is a schematic top view of the semiconductor structure of FIG. 28 in accordance with some embodiments of the present disclosure.

FIG. 30 is a schematic cross-sectional diagram of a portion of a processor die in accordance with some embodiments of the present disclosure.

FIG. 31 is a schematic cross-sectional diagram of a semiconductor structure having different regions for different types of masks in accordance with some embodiments of the present disclosure.

FIG. 32 is a schematic diagram of an RDL of a semiconductor structure being patterned with different types of masks as applied in mask stitching technique.

### DETAILED DESCRIPTION

The following description accompanies drawings, which are incorporated in and constitute a part of this specification, and which illustrate embodiments of the disclosure, but the disclosure is not limited to the embodiments. In addition, the following embodiments can be properly integrated to complete another embodiment.

References to “one embodiment,” “an embodiment,” “exemplary embodiment.” “other embodiments,” “another embodiment,” etc. indicate that the embodiment(s) of the disclosure so described may include a particular feature, structure, or characteristic, but not every embodiment necessarily includes the particular feature, structure, or characteristic. Further, repeated use of the phrase “in the embodiment” does not necessarily refer to the same embodiment, although it may.

In order to make the present disclosure completely comprehensible, detailed steps and structures are provided in the following description. Obviously, implementation of the present disclosure does not limit special details known by persons skilled in the art. In addition, known structures and steps are not described in detail, so as not to unnecessarily limit the present disclosure. Preferred embodiments of the present disclosure will be described below in detail. However, in addition to the detailed description, the present disclosure may also be widely implemented in other embodiments. The scope of the present disclosure is not limited to the detailed description, and is defined by the claims.

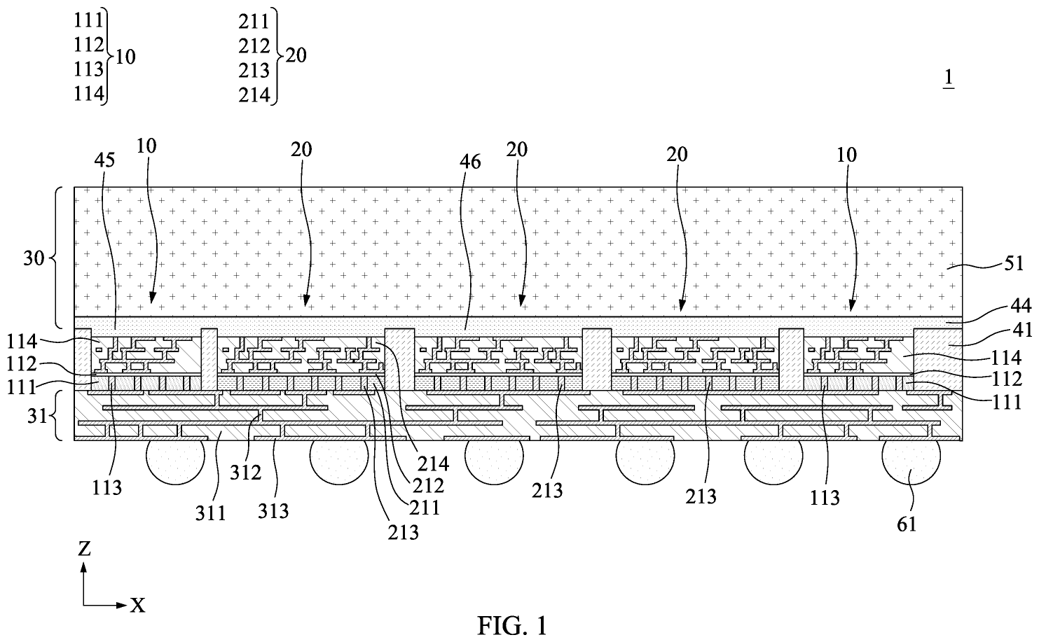

FIG. 1 is a schematic cross-sectional view of a semiconductor structure 1 in accordance with some embodiments of the present disclosure. The semiconductor structure 1 is a package structure, including a plurality of input/output (I/O) dies 10, a plurality of processor dies 20 surrounded by the I/O dies 10, and a redistribution layer (RDL) 31 disposed over the I/O dies 10 and the processor dies 20 for electrical connection and signal transmission between the dies 10 and 20. The semiconductor structure 1 can further include a molding material 41 filling a space between the dies 10 and 20, and a substrate 51 for supporting the semiconductor structure 1 and heat dissipation.

The I/O dies 10 are configured to receive or transmit I/O signals from a back side of the I/O dies 10 through the RDL 31. In some embodiments, an I/O die 10 includes analog circuit, such as I/O circuit, serializer/deserializer (SerDes) circuit, and etc. . . . It should be noted that a number of the I/O dies 10 depends on a requirement of an application, and is not limited herein. The I/O dies 10 may have similar structures. In some embodiments, the I/O die 10 includes a substrate 111, an active area 112 in the substrate 111, an RDL 114 over the substrate 111, and a plurality of back-side through vias (BSTVs) 113 disposed in the substrate 111 and extending along a thickness of the substrate 111.

The substrate 111 includes a front surface and a back surface opposite to the front surface, wherein the active area 112 is formed at the front surface, and the back surface is away from the active area 112. For a purpose of illustration, a side at the back surface of the substrate 111 is referred to as a back side, and a side at the front surface of the substrate 111 is referred to as a front side. The active area 112 is disposed at the front surface of the substrate 111, and the RDL 114 is disposed on the front surface of the substrate 111. In some embodiments, the thickness of the substrate 111 is in a range of 0.2 to 2 microns (μm). In some embodiments, the RDL 114 includes a plurality of metal line layers, a plurality of metal via layers alternately arranged with the metal line layers, and a plurality of dielectric layers (or inter-metal dielectric (IMD) layers) surrounding metal lines of the metal line layers and metal vias of the metal via layers. The metal lines and metal vias are to provide electrical connections between electrical components formed in or on the active area 112. For a purpose of description, the active area 112 (and all other active areas of other substrates illustrated in the following description) can represent not just a doping region but also all electrical components or functional units (e.g., active components, transistors, or diodes) formed thereon. Each of the BSTVs 113 extends from the back surface of the substrate 111 toward the front surface of the substrate 111. The BSTVs 113 are for a purpose of electrical connection and signal transmission from the back side of the substrate 111. In some embodiments, the BSTV 113 penetrates the substrate 111. In some embodiments, the BSTV 113 stops in the substrate 111 and electrically connects to a power rail (or back-side power rail) disposed in the substrate 111 so as to electrically connect the electrical components. In some embodiments, a depth of the BSTV 113 is substantially less than or equal to a thickness of the substrate 111. (A detailed description is provided in the following paragraphs.) In some embodiments, the RDL 31 is referred to as a back-side RDL 31 since it is disposed on the back sides of the I/O dies 10 and on back sides of the processor dies 20.

The processor dies 20 are configured to transmit an electrical signal to the I/O dies 10 or process an electrical signal from the I/O dies 10, wherein the electrical signal is transmitted from the back sides of the processor dies 20 through the RDL 31. In some embodiments, a processor die 20 includes core computing units, a cache memory, and an analog circuit. In some embodiments, the processor die 20 consists of the core computing units, the cache memory, and the analog circuit. In some embodiments, the core computing is a digital circuit. In some embodiments, the cache memory includes static random-access memory (SRAM). In some embodiment, the analog circuit includes physical layer (PHY), SerDes, DTD interface, and etc. . . . It should be noted that a number of the processor dies 20 depends on a requirement of an application, and is not limited herein. The processor dies 20 may have similar structures. In some embodiments, a processor die 20 includes a substrate 211, an active area 212 in the substrate 211, an RDL 214 at the front side of the substrate 211, and a plurality of back-side through vias (BSTVs) 213 disposed in the substrate 211 and extending along a thickness of the substrate 211.

The RDL 31 is a continuous structure disposed on back surfaces of the dies 10 and 20. The RDL 31 can be similar to the RDL 114 or 214 but has a greater dimension. In some embodiments, the RDL 31 includes a plurality of dielectric layers 311 (which can alternatively be referred to as IMD layers 311), a plurality of layers of metal vias 312, and a plurality of layers of metal lines 313. In some embodiments, the dielectric layers 311 extend over the back surfaces of the dies 10 and 20 and cover the dies 10 and 20 for signal transmission and electrical connection from the back sides of the dies 10 and 20. A lower surface of the molding material 41 may be substantially coplanar with back surfaces of the I/O dies 10 and the back surfaces of the processor dies 20. In some embodiments, the RDL 31 covers the planar surface, which is composed of the lower surface of the molding material 41 and the back surfaces of the I/O dies 10 and the processor dies 20. Each of the dielectric layers 311 of the RDL 31 is a monolithic structure. In some embodiments, each of the dielectric layers 311 is a continuous layer extending across an entire lower surface of the molding material 41. In some embodiments, each of the dielectric layers 311 of the RDL 31 overlaps the molding material 41 along a stacking direction of the dies (including the dies 10 and 20) and the RDL 31. In some embodiments, the lower surface of the molding material 41 is in direct contact with a dielectric layers 311, which being a first dielectric layer on the back surfaces of the I/O dies and the processor dies. The metal lines 313 and the metal vias 312 of the RDL 31 may or may not overlap the molding material 41 between the dies 10 and 20 along the stacking direction according to different applications.

As shown in FIG. 1, each of the dies 10 and 20 includes multiple BSTVs (i.e., 113 and 213) for a purpose of back-side signal transmission. In some embodiments, each of the BSTVs 113 and 213 is electrically connected to one of the metal lines 313 of the RDL 31. A dimension of the BSTVs 113 can be similar to or substantially the same as a dimension of the BSTVs 213. In some embodiments, an aspect ratio, which is a ratio of a width to a depth, is less than ⅕. For example, when the depth of the BSTV 113 or 213 is about 500 nanometers (nm), the width is less than 100 nm. In some embodiments, each of the BSTVs 113 and 213 is in direct contact with the metal line 313 of the RDL 31. In some embodiments, each of the BSTVs 113 and 213 is electrically connected to one of the metal vias 312 of the RDL 31.

The semiconductor structure 1 may further include a plurality of connectors 61, disposed over the RDL 31 on a side opposite to the dies 10 and 20. In some embodiments, electrical signals are transmitted to or from the dies 10 and 20 through the RDL 31 and the connectors 61. In some embodiments, the electrical signals enter a die 10 through one or more of the BSTVs 113 of the I/O die 10, and the electrical signals are then transmitted to electrical components in the active area 112 of the I/O die 10. In some embodiments, voltages for power supply are provided to the dies 10 and 20 through their BSTVs 113 and 213, the RDL 31 and the connectors 61.

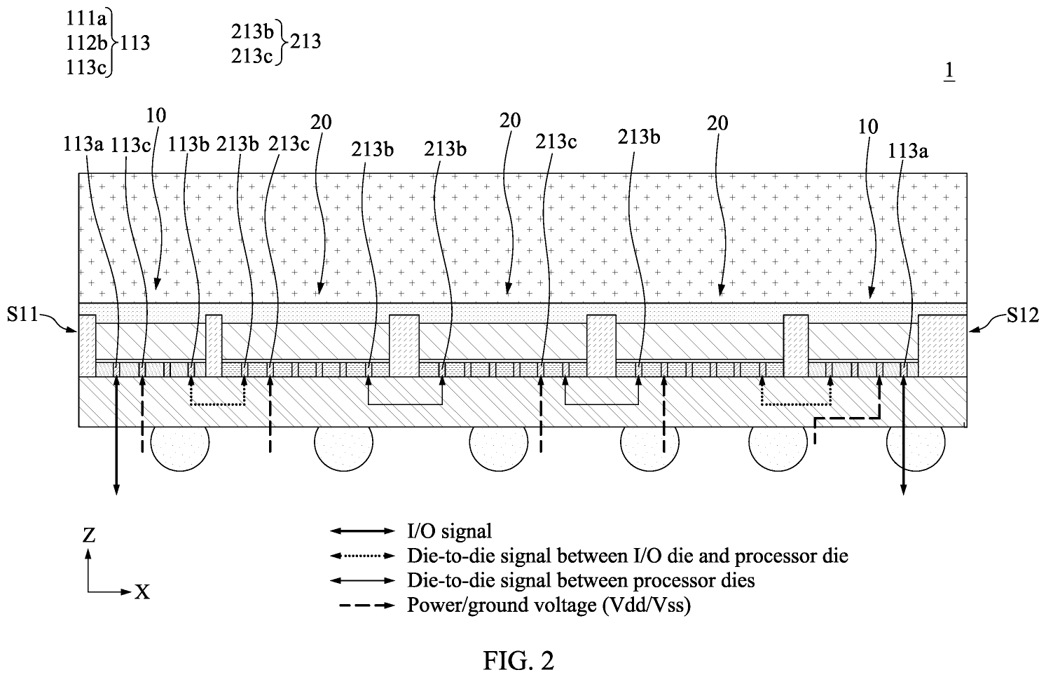

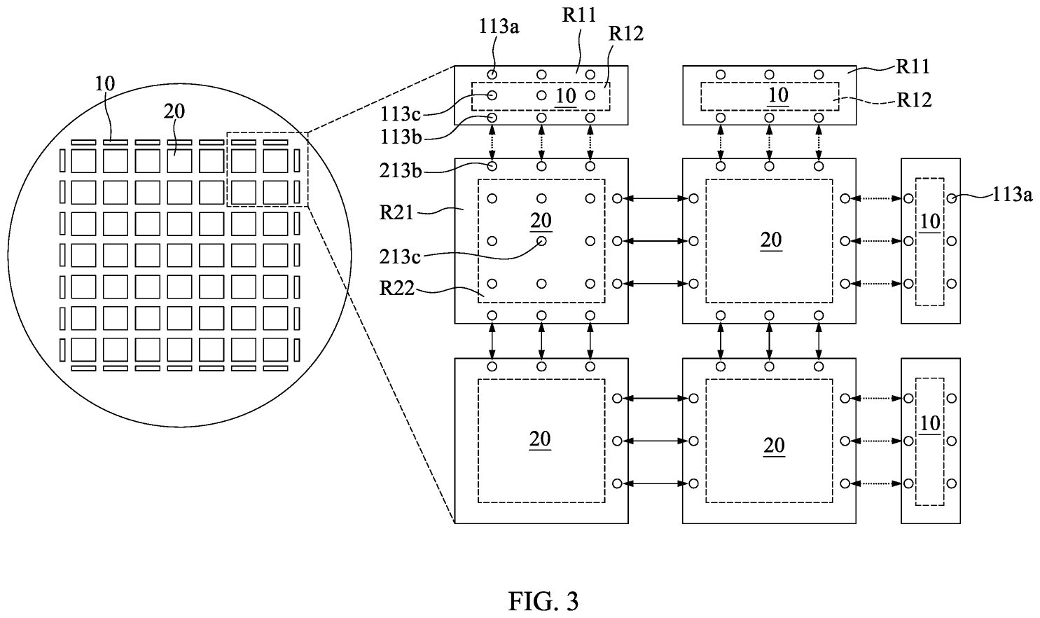

The semiconductor structure 1 is designed for signal transmission between dies (e.g., the dies 10 and 20) at the back sides of the dies. FIGS. 2 and 3 are schematic diagrams of the semiconductor structure 1 showing the signal transmission between the dies 10 and 20, and signal transmission into and out of the semiconductor structure 1. Arrows with different types of dashed lines shown in FIGS. 2 and 3 indicate different types of electrical signals and directions of the signals for a purpose of illustration, wherein FIG. 2 illustrates the signal transmissions from a cross-sectional perspective, and FIG. 3 illustrates the signal transmissions from a top-view perspective. In some embodiments as shown in FIG. 3, the I/O dies 10 surround the processor dies 20 from a top view. It should be noted that, for a purpose of simplicity and case of understanding, details of the RDLs 114, 214 and 31 are omitted in FIG. 2. For a purpose of illustration, signals transmitted into and out of the semiconductor structure 1 are referred to as I/O signals, and signals transmitted between the dies 10 and 20 of the semiconductor structure 1 are referred to as die-to-die (DTD) signals. Transmission paths of the signals can be split (or grouped) according to different types of signals to improve signal quality and transmission speed.

As shown in FIGS. 2 and 3, an I/O signal may be provided to at least one of the connectors 61, and the I/O signal is then transmitted to one of the I/O dies 10 through the RDL 31 and one or more BSTVs 113 of the I/O die 10. Another I/O signal can also be transmitted from the I/O die 10 to one or more of the connectors 61 through the one or more BSTVs 113 of the I/O die 10 and the RDL 31. In order to split the I/O signals from the DTD signals, the BSTVs 113 that are for transmitting the I/O signals are arranged in a portion peripheral region R11 of the I/O die 10 away from adjacent dies. In some embodiments, those of the BSTVs 113 that are for transmitting the I/O signals are arranged in the portion of the peripheral region R11 of the I/O die 10, wherein the portion of the peripheral region R11 faces (or is proximal to) sidewalls (e.g., S11 and S12) of the semiconductor structure 1. For a purpose of illustration, the BSTVs 113 that are for transmitting I/O signals, are labeled as BSTVs 113a.

The DTD signals are transmitted between the dies 10 and 20 through the BSTVs 113 and 213 and the RDL 31. For a purpose of minimizing a length of an electrical path for DTD signal transmission thereby improving signal quality and transmission speed, the DTD signals are transmitted through BSTVs 113b of the BSTVs 113 and BSTVs 213b of the BSTVs 213. The BSTVs 113b indicate those of the BSTVs 113 that are disposed in another portion of the peripheral region R11 of the I/O die 10 facing (or proximal to) an adjacent processor die 20 for transmitting DTD signals, and the BSTVs 213b indicate those of the BSTVs 213 that are disposed in the peripheral region R21 of the processor die 20 for transmitting DTD signals. In order to provide electrical paths in the RDL 31 between adjacent dies, the RDL 31 may include a metal line 313 at least partially disposed in an area of vertical projection of the molding material 41.

It should be noted that the BSTVs 113a shown in FIGS. 2 and 3 are arranged in a line for a purpose of illustration. A number and an arrangement of the BSTVs 113a are not limited thereto. Similarly, a number and an arrangement of the BSTVs 113b and 213b shown in FIGS. 2 and 3 are for a purpose of illustration but are not intended to limit the present disclosure. In some embodiments, the BSTVs 213b are arranged in a rectangular ring as shown in FIG. 3. In some embodiments, the BSTVs 213b are arranged in multiple rectangular rings in the peripheral region R21 of a processor die 20. In some embodiments, the BSTVs 213b are arranged alternately in the peripheral region R21 of a processor die 20.

Voltages can be provided to the I/O dies 10 and the processor dies 20 from the back side of the semiconductor structure 1 for a purpose of power supply (e.g., positive supply voltage or Vdd) or ground voltage (e.g., zero voltage or Vss). In some embodiments, a voltage is provided to a connector 61, and the voltage is then transmitted to one of the dies 10 and 20 through the RDL 31 and a BSTV 113 or 213 of the corresponding die 10 or 20. For a purpose of signal split, the power voltage or the ground voltage is electrically connected to at least a BSTV 113c in a central region R12 of the I/O die 10 or at least a BSTV 213c in a central region R22 of the processor die 20. In some embodiments, the central region R12 is surrounded by the peripheral region R11 of the I/O die 10, and at least one BSTV 113c of the BSTVs 113 are disposed in the central region R12. In some embodiments, the power voltage and/or the ground voltage is provided to the BSTV 113c of the I/O die 10. In some embodiments, the central region R22 is surrounded by the peripheral region R21 of the processor die 20, and the BSTV 213c of the BSTVs 213 are disposed in the central region R22. In some embodiments, the power voltage and/or the ground voltage is provided to the BSTV 213c of the processor die 20.

In a traditional semiconductor package, all signals (including I/O signals and DTD signals) are transmitted through an RDL disposed on front sides of dies in the semiconductor package. However, as technology advances increasing use of small sizes in each generation in the field, space for routing of electrical paths for signal transmission is very limited, and issues of noise and device efficiency have been encountered, especially for chips of 3-nm scale and beyond (e.g., an anticipated 2-nm generation of chips). The present disclosure provides a semiconductor structure that is capable of transmitting signals on both front sides and back sides of dies in the semiconductor structure to solve the issue encountered in the field by splitting signal transmissions.

As described above, the semiconductor structure 1 of the present disclosure is capable of transmitting DTD signals and I/O signals from the back sides of the dies 10 and 20. In some embodiments, signals are transmitted between electrical components within an I/O die 10 through the RDL 114 of the I/O die 10. In some embodiments, signals are transmitted between electrical components within a processor die 20 through the RDL 214 of the processor die 20. In some embodiments, only DTD signals, I/O signals, power voltage and ground voltage are transmitted through the RDL 31 and the BSTVs 113 and 213 at the back sides of the dies, and layout design of electrical connections of the RDL 31 can be simplified. Therefore, transmission speed can be improved, and signal loss or noise can be also reduced.

Referring back to FIG. 1, the I/O dies 10 and the processor dies 20 may be bonded to the substrate 51 for handling the dies 10 and 20 and supporting the semiconductor structure 1. In some embodiments, the substrate 51 is a silicon wafer. In some embodiments, the substrate 51 is bonded to the I/O dies 10 and the processor dies 20 at the front sides of the I/O dies 10 and the processor dies 20. In some embodiments, bonding layers 44, 45 and 46 are disposed on the substrate 51, the I/O dies 10, and the processor dies 20, respectively. In some embodiments, the I/O dies 10 and the processor dies 20 are bonded to the substrate 51 by fusion bonding, and the bonding layers 44, 45 and 46 include only dielectric material. In some embodiments, the substrate 51 and the bonding layer 44 are collectively referred to as a semiconductor structure 30. However, the present disclosure is not limited thereto. In other embodiments, the I/O dies 10 and the processor dies 20 are bonded to the substrate 51 by hybrid bonding, or the substrate 51 can be a functional substrate.

In the following paragraphs, various embodiments are provided. For a purpose of clarity and simplicity, reference numbers of elements with same or similar functions are repeated in different embodiments. However, such usage is not intended to limit the present disclosure to specific embodiments or specific elements. In addition, conditions or parameters illustrated in different embodiments can be combined or modified to form different combinations of embodiments as long as the parameters or conditions used are not in conflict.

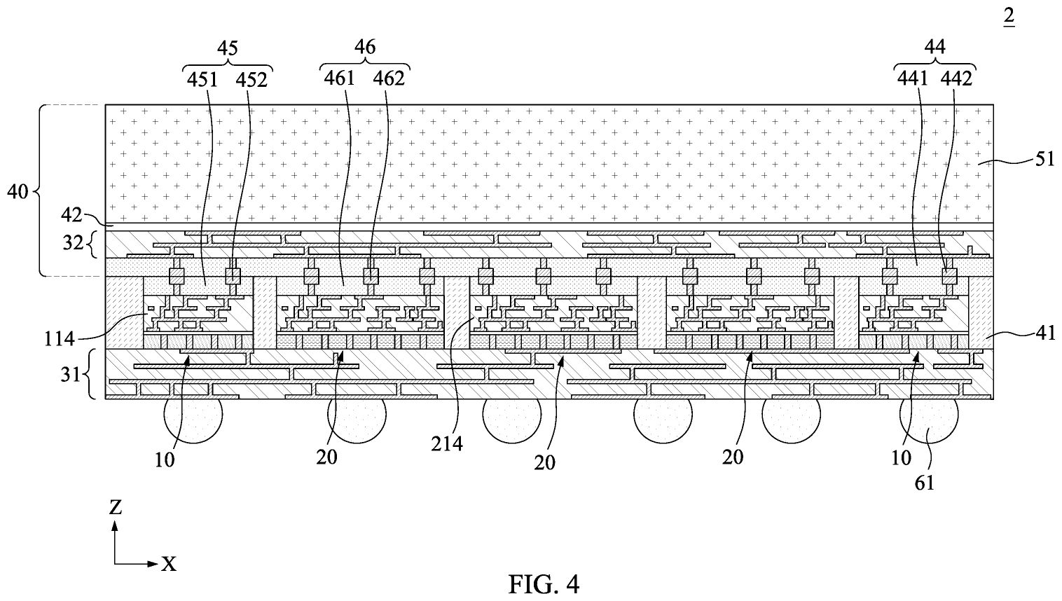

FIG. 4 is a schematic cross-sectional view of a semiconductor structure 2 in accordance with some embodiments of the present disclosure. The semiconductor structure 2 can be similar to the semiconductor structure 1 but further includes an RDL 32 over the substrate 51. In some embodiments, a dielectric layer 42 is disposed between the RDL 32 and the substrate 51. The RDL 32 can be similar to the RDL 31. The RDL 32 may include metal line layers, metal via layers, and dielectric layers. In some embodiments, the bonding layer 44, the dielectric layer 42 and the substrate 51 are collectively referred to as a semiconductor structure 40. In some embodiments, in order to provide electrical connection to the RDL 32, each of the bonding layers 44, 45 and 46 includes metallic features at bonding interfaces between the I/O dies 10 and the semiconductor structure 40 and between the processor dies 20 and the semiconductor structure 40. In some embodiments, the bonding layers 44, 45 and 46 are hybrid bonding layers. Details of a structure of the RDL 32 are same as those of the RDL 31, and can be found by referring to the description of the RDL 31 above; thus, repeated description is omitted herein.

Each of the bonding layers 44, 45 and 46 may include a plurality of metallic features surrounded by a dielectric layer. The metallic features can include metal lines, metal traces, metal vias or a combination thereof. Each of the metallic features can provide electrical connections across the dielectric layer. In some embodiments, the hybrid bonding layer 44 includes a plurality of metallic features 442 and a dielectric layer 441 surrounding the metallic features 442. In some embodiments, the hybrid bonding layer 45 includes a plurality of metallic features 452 and a dielectric layer 451 surrounding the metallic features 452. In some embodiments, the hybrid bonding layer 46 includes a plurality of metallic features 462 and a dielectric layer 461 surrounding the metallic features 462.

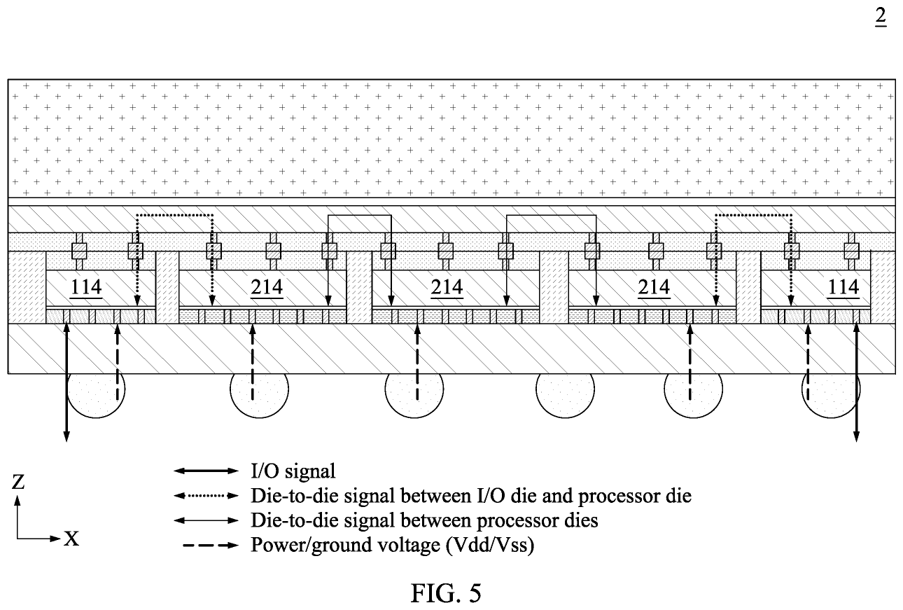

FIG. 5 is a schematic diagram of the semiconductor structure 2 showing signal transmission between the dies 10 and 20, and signal transmission into and out of the semiconductor structure 2. Arrows shown in FIG. 5 indicate different types of electrical signals for a purpose of illustration.

The RDL 32 can provide electrical paths between the dies (including the I/O dies 10 and the processor dies 20) for DTD signal transmission. Referring to FIGS. 4 and 5, similar to the semiconductor structure 1, transmission of I/O signals, power supply, and ground connection of the semiconductor structure 2 can be achieved on the back sides of the dies by the BSTVs 113 and 213 through the RDL 31 and the connectors 61. In the semiconductor structure 2. DTD signals can be optionally transmitted on the front sides of the dies through the metallic features in the hybrid bonding layers 44, 45 and 46 and the RDL 32. In some embodiments, the DTD signal is transmitted between an I/O die 10 and an adjacent processor die 20 through the RDL 114, the metallic features 452 of the hybrid bonding layer 45, the RDL 32, the metallic features 462 of the hybrid bonding layer 46, and the RDL 214. In some embodiments, the DTD signal is transmitted between adjacent processor dies 20 through the RDLs 214 of the processor dies 20, the metallic features 462 of the hybrid bonding layer 46, and the RDL 32.

Compared to the semiconductor structure 1, transmission paths of the DTD signals may be longer but a number of the BSTVs 113 or 213 in each of the I/O dies 10 or the processor dies 20 can be reduced, and a complexity of electrical paths in the RDL 31 can be also reduced. This can be advantageous to achieving a better performance of splitting signals and reduction of signal noises, especially for advanced generations of chips or dies.

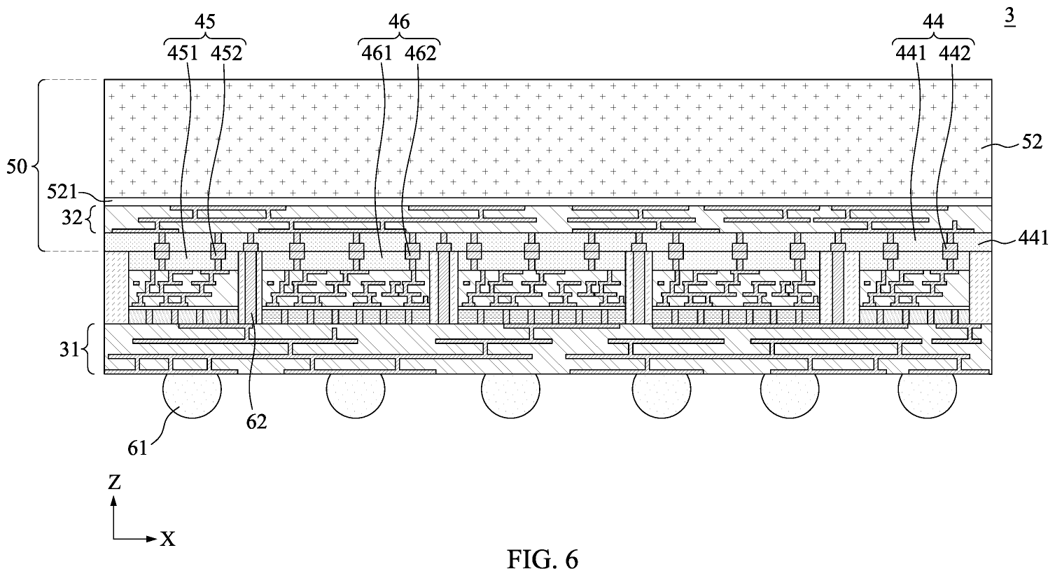

FIG. 6 is a schematic cross-sectional view of a semiconductor structure 3 in accordance with some embodiments of the present disclosure. The semiconductor structure 3 can be similar to the semiconductor structure 2 but includes a substrate 52 including an active area 521, wherein the active area 521 includes electrical or functional components formed in or on the active area 521. The RDL 32 is disposed on the substrate 52 to provide electrical connection to the electrical components in or on the active area 521. In some embodiments, the electrical components of the substrate 52 include memory units (e.g., static random-access memory (SRAM) units). The semiconductor structure 3 may further include at least one through molding via (TMV) 62 for power supply to the active area 521 of the substrate 52.

In some embodiments, the TMV 62 is disposed between adjacent dies (including the dies 10 and 20). In some embodiments, the TMV 62 penetrates the molding material 41. In some embodiments, The RDL 31 and the RDL 32 are electrically coupled through the TMV 62. In some embodiments, a power voltage or a ground voltage is provided to the substrate 52 through the RDL 31 and the TMV 62. In some embodiments, the TMV 62 contacts a metal line in the RDL 31 and the metallic feature 442 of the hybrid bonding layer 44.

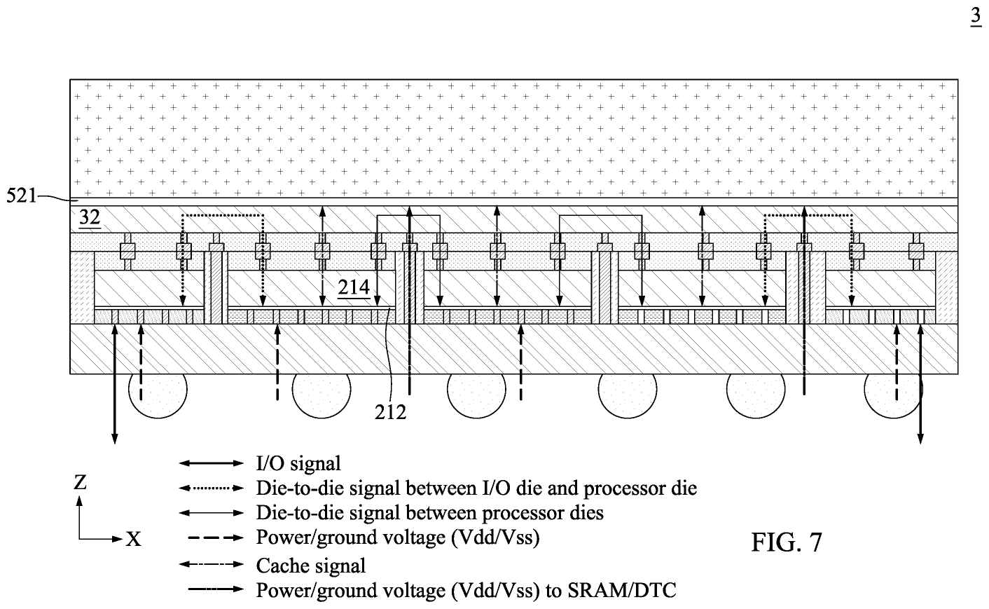

FIG. 7 is a schematic diagram of the semiconductor structure 3 showing DTD signal transmission between the dies 10 and 20, I/O signal transmission into and out of the semiconductor structure 3, and cache signal transmission between a die (e.g., the I/O die 10 or the processor die 20) and the substrate 52. For a purpose of illustration, signals transmitted between one of the processor dies 20 and one of the memory units are referred to as cache signals. Arrows shown in FIG. 7 indicate different types of electrical signals for a purpose of illustration.

Please refer to FIGS. 6 and 7. In some embodiments, the electrical components of the substrate 52 include memory cells (e.g., dynamic random-access memory (DRAM) cells, static random-access memory (SRAM) cells, etc.). In some embodiments, the electrical components of the substrate 52 include deep trench capacitors (DTC). In some embodiments, a cache signal is transmitted between a processor die 20 and the substrate 52 through the hybrid bonding layers 44 and 46. More specifically, in some embodiments, a cache signal is transmitted between the active area 212 and the active area 521 through the RDL 214, the metallic features 462 of the hybrid bonding layer 46, the metallic features 442 of the hybrid bonding layer 44, and the RDL 32. In addition, in order to achieve a purpose of a back-side power delivery network, a power voltage or a ground voltage can be provided to the substrate 52 from the connectors 61 through the RDL 31, the TMV 62, the hybrid bonding layer 44, and the RDL 32. Therefore, the semiconductor structure 3 with the back-side power delivery network configured to split signals so as to improve signal quality and transmission rate can be achieved.

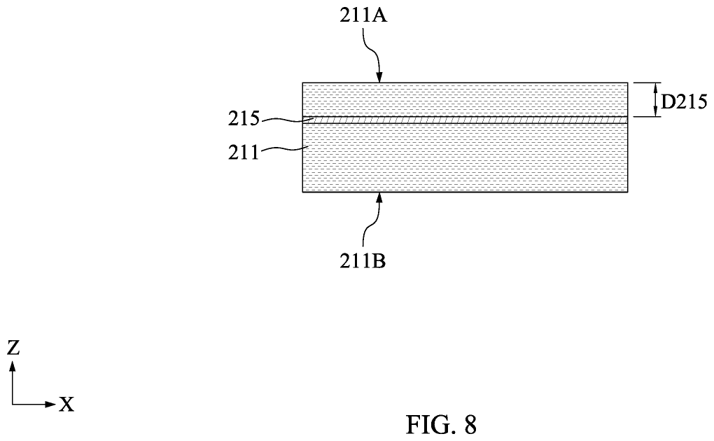

FIGS. 8 to 30 are schematic diagrams of a semiconductor structure at different stages or different perspectives of a manufacturing method in accordance with some embodiments of the present disclosure. For a purpose of illustration, the manufacturing method focuses on a formation of a processor die 20 applied in a semiconductor package, as illustrated in FIGS. 8 to 30 as an exemplary embodiment. However, the present disclosure is not limited thereto.

Referring to FIG. 8, a substrate 211 is received, provided, or formed. The substrate 211 includes a first surface (or a front surface) 211A and a second surface (or a back surface) 211B opposite to the first surface 211A. In some embodiments, the substrate 211 includes a bulk semiconductor material, such as silicon. The substrate 211 may include another elementary semiconductor, such as germanium; a compound semiconductor including silicon carbide, gallium arsenic, gallium phosphide, indium phosphide, indium arsenide, or indium antimonide; an alloy semiconductor including SiGe, GaAsP, AlInAs, AlGaAs, GalnAs, GaInP, or GaInAsP; or combinations thereof. In some embodiments, a thickness of the substrate 211 at this stage is about 775 microns (μm).

An etch stop layer 215 is formed in the substrate 211. In some embodiments, a distance D215 between the etch stop layer 215 and the front surface of the substrate 211 is in a range of 0.2 to 2 microns (μm). In some embodiments, the distance D215 is substantially equal to or less than 1 μm. The etch stop layer 215 can be a doping layer. In some embodiments, germanium is doped in the substrate 211 to form the etch stop layer 215. The etch stop layer 215 can also be an epitaxial layer having a semiconductive material different that of the substrate 211. In some embodiments, the etch stop layer 215 is a SiGe layer epitaxially grown over a silicon wafer, and another silicon layer is then epitaxially grown over the SiGe layer to form the etch stop layer 215 in the substrate 211 as shown in FIG. 8. In some embodiments, the substrate 211 is a silicon-on-insulator (SOI) substrate, wherein the insulator of the SOI substrate is embodied as the etch stop layer 215.

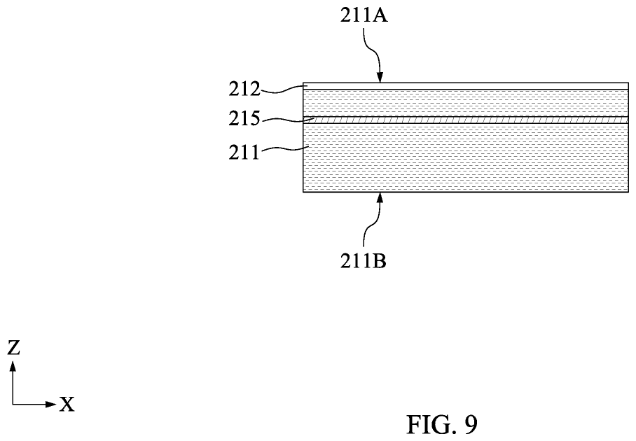

Referring to FIG. 9, an active area 212 is formed in the substrate 211. The active area 212 can be formed or defined in the substrate 11 at the first surface 211A. The active area 211 may be of a first conductivity type, e.g., a P-type (acceptor type) doping area, or of a second conductivity type, e.g., an N-type (donor type) doping area. In some embodiments, the active area 211 may include a doped epitaxial layer, a gradient semiconductor layer, or a semiconductor layer overlaying another semiconductor layer of a different type, such as a silicon layer on a silicon germanium layer. A portion of the substrate 211 below the active area 212 can be an intrinsic area or non-doping area at this stage. In addition, X and Z directions are depicted on the figures, wherein the X direction define a horizontal direction or a surface direction (e.g., an extending direction of the first surface 211A or the second surface 211B) of the substrate 211, and the Z direction defines a direction that is normal to the surface of the substrate 211. In some embodiments, the active area 212 is separated from the etch stop layer 215 by a portion of the intrinsic area or the non-doping area of the substrate 211. In some embodiments, the etch stop layer 215 is substantially parallel to the first surface 211A along the X direction.

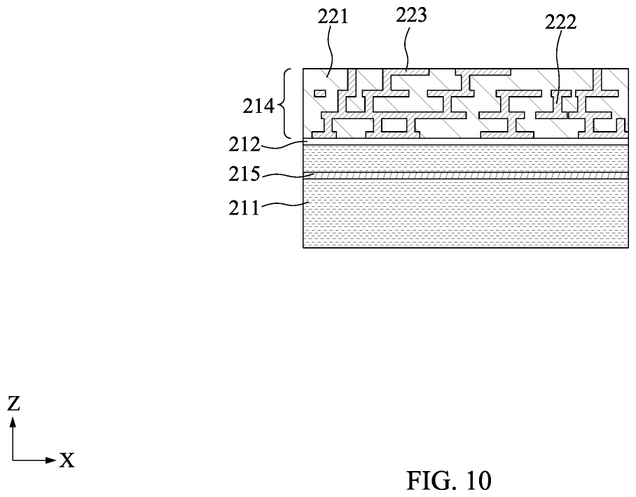

Referring to FIG. 10, an RDL 214 is formed on the first surface 211A of the substrate 211 in accordance with some embodiments of the present disclosure. In some embodiments, the RDL 214 covers an entirety of the active area 212. The RDL 214 includes multiple metal line layers and multiple metal via layers arranged alternately between the metal line layers for electrical connection between the metal line layers. In some embodiments, each metal line layer is formed of metal lines 223 and an inter-metal dielectric (IMD) layer 221 surrounding the metal lines 223. In some embodiments, each metal via layer is formed of metal vias 222 and the IMD layer 221 surrounding the metal vias 222. A number of the metal line layers of the RDL 214 can be adjusted according to different applications, and is not limited herein.

It should be noted that the figures are for a purpose of illustration of the present disclosure, and some details of the semiconductor structure may be omitted from the figures for a purpose of simplicity and clarity. For example, a plurality of electrical components are formed on the substrate 11 in the active area 211 prior to or during the formation of the RDL 214. The electrical components can be active components or devices, and may include different types or generations of devices. In some embodiments, the electrical components can include a planar transistor, a multi-gate transistor, a gate-all-around field-effect transistor (GAAFET), a fin field-effect transistor (FinFET), a vertical transistor, a nanosheet transistor, a nanowire transistor, a passive device, a capacitor, a plurality thereof, or a combination thereof. In some embodiments, the electrical components are for processing information to complete a task, and the substrate 211 is referred to as a logic wafer. In some embodiments, the electrical components include memory cells (e.g., dynamic random-access memory (DRAM) cells, static random-access memory (SRAM) cells, etc.). In some embodiments, the electrical components are for data storage, and the substrate 211 is referred to as a memory wafer. In some embodiments, an interconnect structure (not shown in the figures) can be formed on the front surface 211A of the substrate 211 prior to the formation of the RDL 214. In some embodiments, the interconnect structure can be formed after or concurrently with the formation of the electrical components. The electrical components and the interconnect structure can be formed following conventional methods of manufacturing semiconductors. For ease of understanding and illustration, in the following description, the electrical components and the interconnect structure are considered as a part of the substrate 211, and the RDL 214 is formed on the substrate 211 including those electrical components and the interconnect structure.

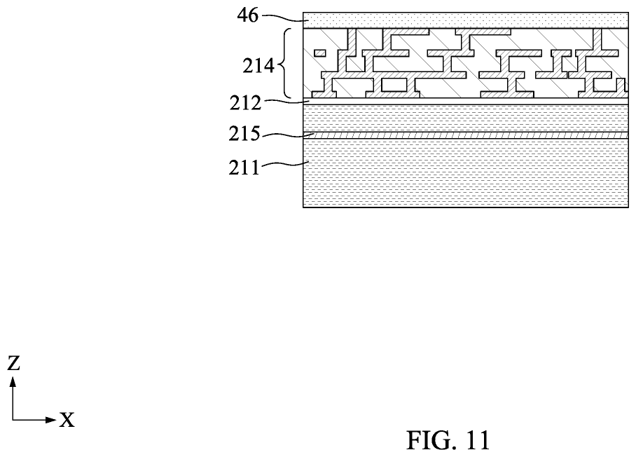

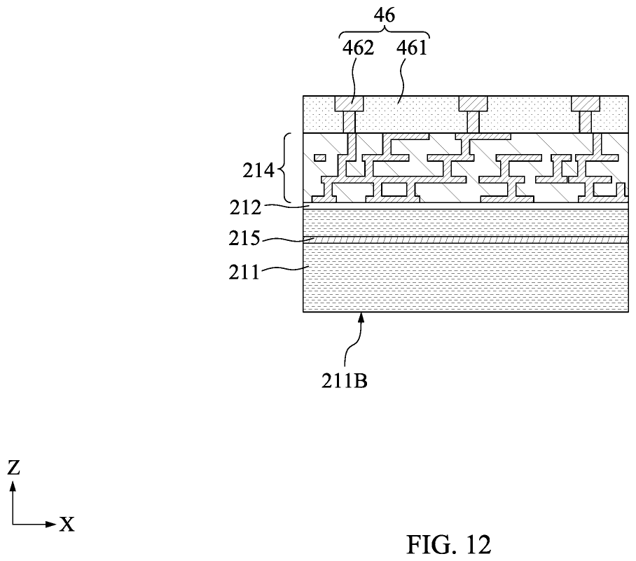

Referring to FIGS. 11 and 12, a bonding layer 46 is formed on the RDL 214 in accordance with some embodiments of the present disclosure. The bonding layer 46 may or may not include metallic material depending on different applications. In some embodiments, a fusion bonding operation is to be performed, and the bonding layer 46 includes only dielectric material (e.g., oxide material or silicon oxide) as shown in FIG. 11. In other embodiments, if a hybrid bonding operation is to be performed, the bonding layer 46 includes metallic features 462 surrounded by a dielectric layer 461 as shown in FIG. 12. In some embodiments, a thickness of the bonding layer 46 is in a range of 0.5 to 5 μm. For a purpose of illustration, the intermediate structure shown in FIG. 11 is used in the following processing of the semiconductor manufacturing method as an exemplary embodiment.

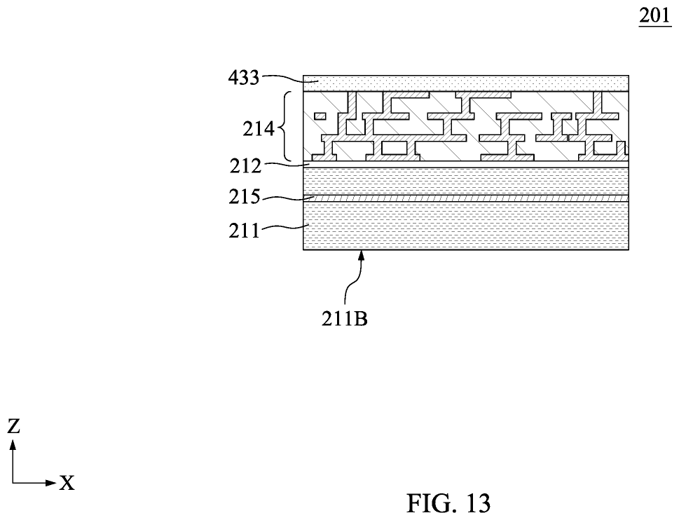

Referring to FIG. 13, a thickness of the substrate 211 is reduced. In some embodiments, the thickness of the substrate 211 is reduced from about 775 μm to about 100 μm. In some embodiments, the thickness of the substrate 211 at this stage is in a range of 70 to 200 μm. In some embodiments, a back-side grinding operation is performed on the second surface 211B of the substrate 211. In some embodiments, the substrate 211 is flipped over and then a thin-down process is performed on the second surface 211B. The thin-down process may include a chemical-mechanical polishing (CMP), a grinding operation, an etching operation, or a combination thereof. A semiconductor structure 201 is thereby formed as an intermediate die (or chip) as shown in FIG. 13.

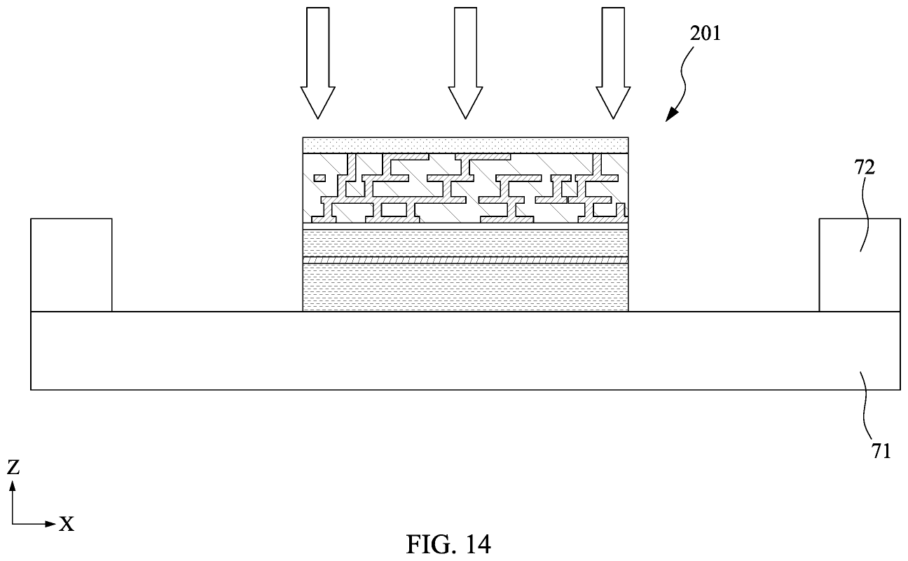

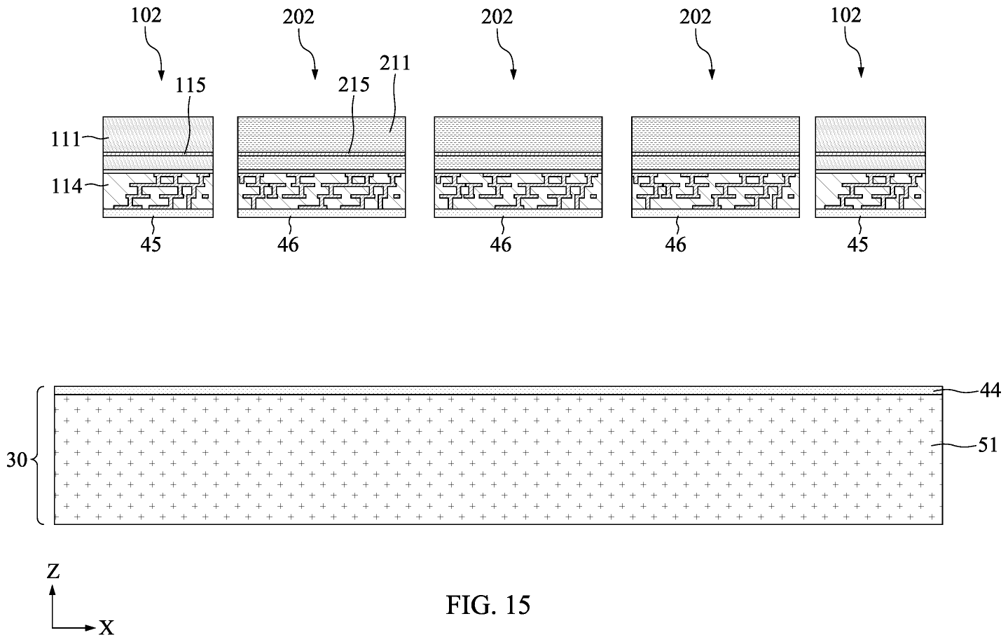

Referring to FIG. 14, a dicing operation is performed to saw the semiconductor structure 201 into multiple dies 202 (the dies 202 are shown in FIG. 15, and are intermediate structures of the processor dies 20 shown in FIG. 1) in accordance with some embodiments of the present disclosure. In some embodiments, the semiconductor structure 201 shown in FIG. 13 is mounted on a frame 72 and attached to a dicing tape 71 on the second surface 211B of the substrate 211 prior to the dicing operation.

Referring to FIGS. 15 to 17, a plurality of dies 202 and a plurality of dies 102 are moved over a substrate 51 or 52 in accordance with some embodiments of the present disclosure. In some embodiments, the dies 202 shown in FIG. 15 are intermediate structures of the processor dies 20 shown in FIG. 1, 4 or 6. In some embodiments, the dies 102 shown in FIG. 15 are intermediate structures of the I/O dies 10 shown in FIG. 1, 4 or 6. The dies 102 can be formed following operations and processing similar to those depicted in FIGS. 8 to 14, and repeated description is omitted herein. In some embodiments, each of the dies 102 includes an etch stop layer 115 in a substrate 111. In some embodiments, for a purpose of bonding to the substrate 51 or 52, each of the dies 102 includes a bonding layer 45 over an RDL 114.

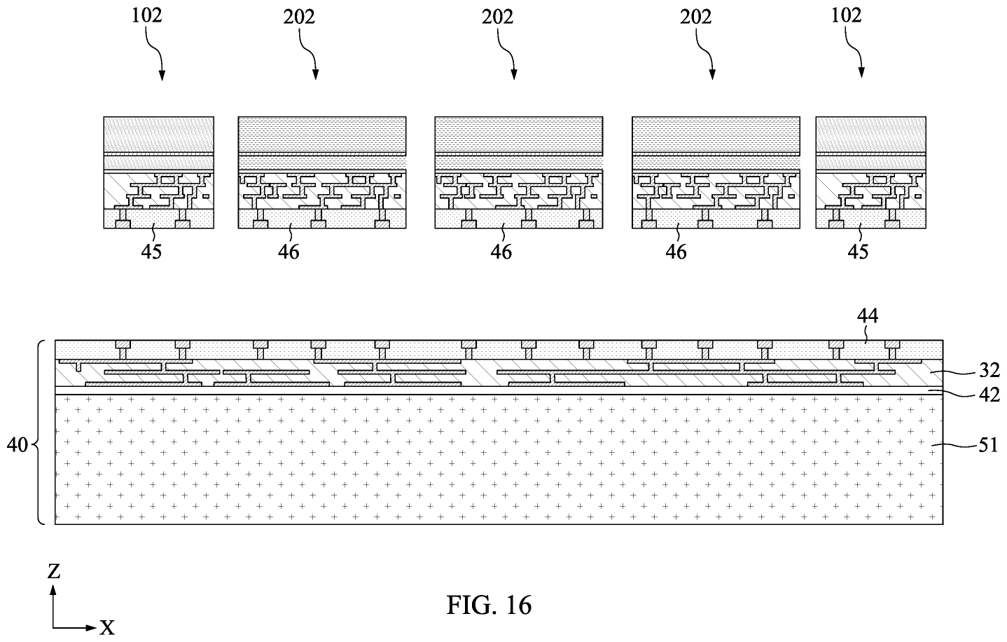

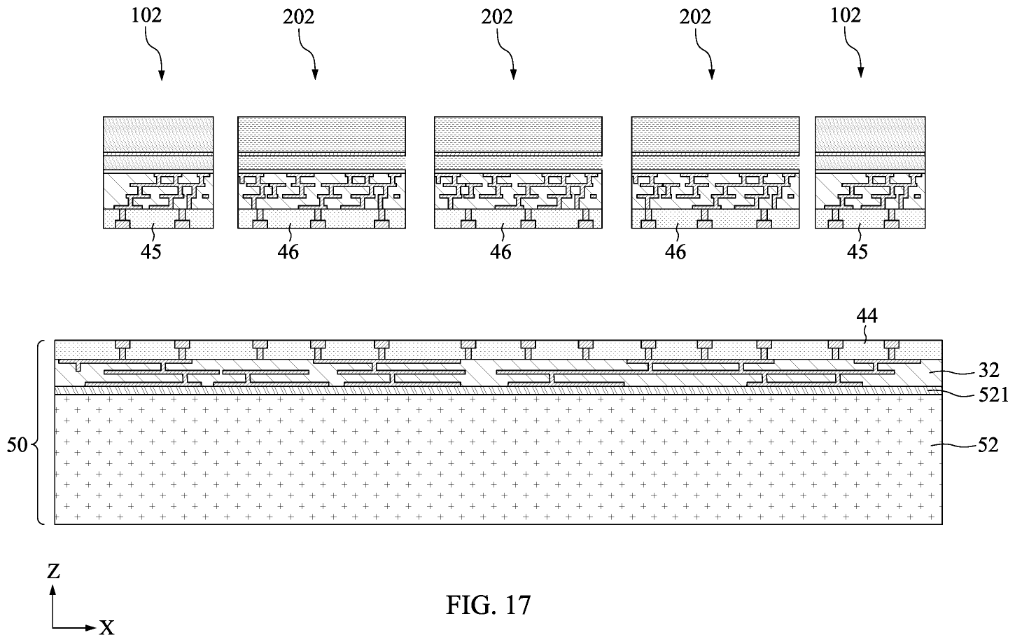

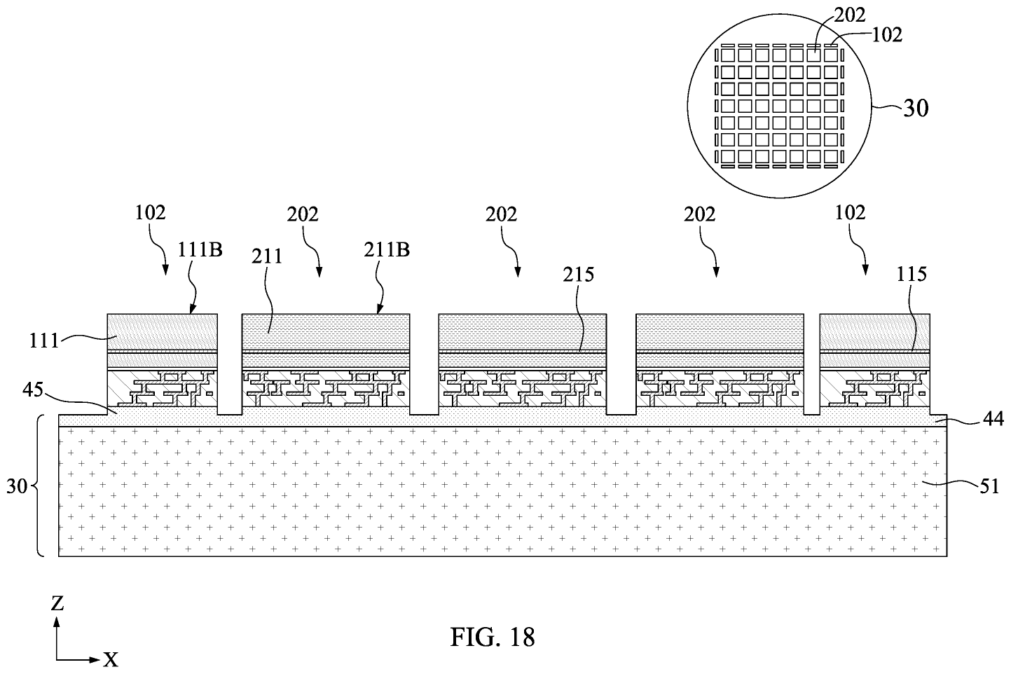

In some embodiments, in order to form the semiconductor structure 1 as shown in FIG. 1, the dies 202 and 102 are moved over a semiconductor structure 30 as shown in FIG. 15. In some embodiments, in order to form the semiconductor structure 2 as shown in FIG. 4, the dies 202 and 102 are moved over a semiconductor structure 40 as shown in FIG. 16. In some embodiments, in order to form the semiconductor structure 3 as shown in FIG. 6, the dies 202 and 102 are moved over a semiconductor structure 50 as shown in FIG. 17. A fusion bonding operation or a hybrid bonding operation is then performed depending on different applications. For a purpose of illustration, only formation of the semiconductor structure 1 as shown in FIG. 1 is illustrated in FIGS. 18 to 26 as an exemplary embodiment.

Referring to FIG. 18, a fusion bonding operation is performed after the dies 202 and 102 are attached over the semiconductor structure 30. In some embodiments, bonding interfaces between the bonding layers 45 and 44 and between the bonding layers 46 and 44 are invisible after the bonding operation. In some embodiments, the bonding layers 45 and 44 are fused, and the bonding layers 46 and 44 are fused to form one observable bonding layer. In some embodiments, the dies 102 and 202 are arranged in an array, wherein a top view of the intermediate structure is shown on an upper right side of FIG. 18. Back surfaces 111B of the substrates 111 and the back surfaces 211B (i.e., the second surface 211B; for ease of understanding, the second surface 211B is referred to as the back surface 211B in the following description) of the substrates 211 are exposed and face upward at this stage. In some embodiments, the back surfaces 111B and 211B are substantially aligned along the X direction. In some embodiments, the etch stop layers 115 and 215 are at a same elevation. In some embodiments, the etch stop layers 115 and 215 are substantially aligned along the X direction.

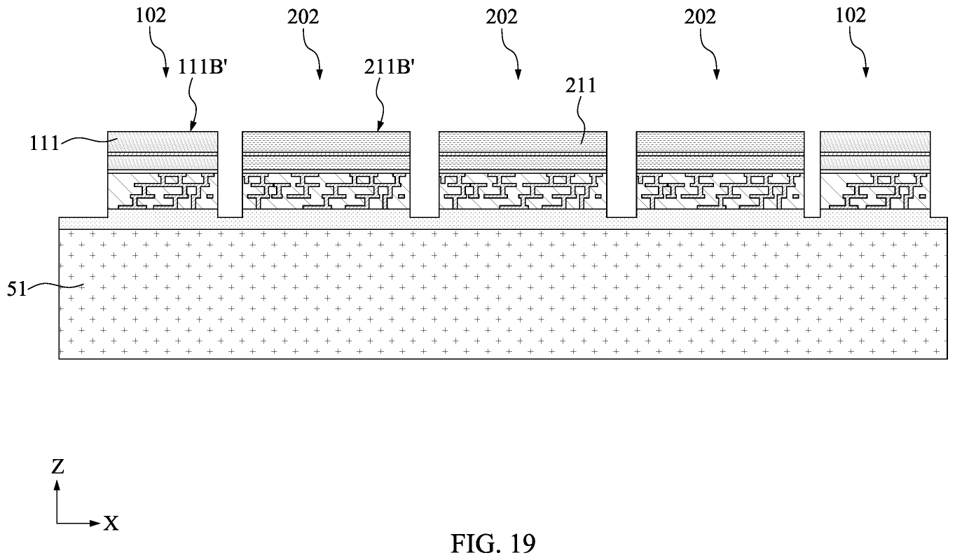

Referring to FIG. 19, thicknesses of the substrates 111 and 211 are reduced in accordance with some embodiments of the present disclosure. In some embodiments, a portion of each of the substrates 111 proximal to the back surface 111B is removed, and a portion of each of the substrates 211 proximal to the back surface 211B is removed. In some embodiments, the portions of the substrates 111 and the portions of the substrate 211 are removed by a grinding operation, and the back surfaces of the substrate 111 and 211 are relabeled to be back surfaces 111B′ and back surfaces 211B′ respectively after the operations as depicted in FIG. 19 for a purpose of illustration. In some embodiments, the thickness of the substrate 111 is substantially equal to the thickness of the substrate 211 after the operations as depicted in FIG. 19. In some embodiments, the thickness of the substrate 111 or 211 is in a range of 10 to 50 μm at this stage. In some embodiments, the thickness of the substrate 111 or 211 is in a range of 10 to 30 μm at this stage.

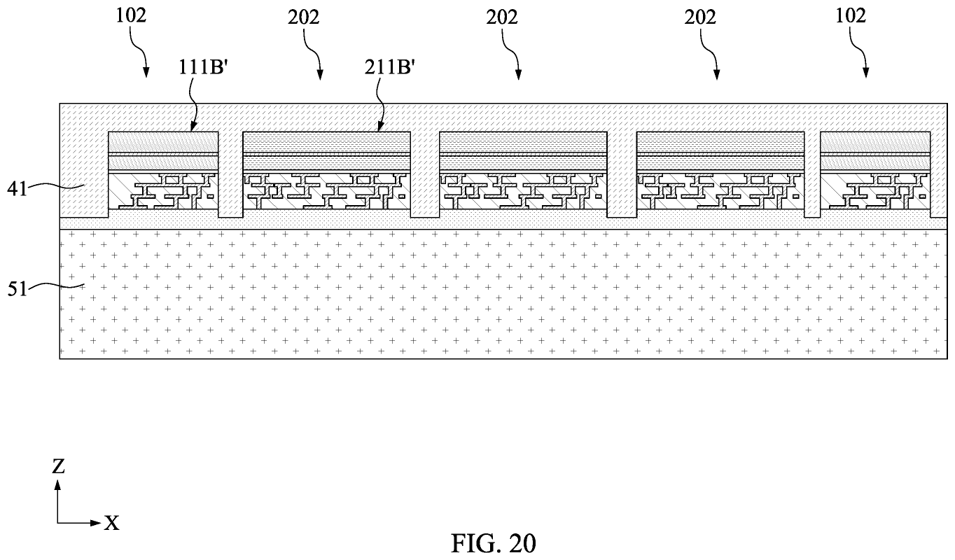

Referring to FIG. 20, a molding material 41 is formed covering the dies 102 and 202 and filling gaps between adjacent dies 102 and 202 in accordance with some embodiments of the present disclosure. In some embodiments, the molding material 41 can be referred to as a gap fill layer 41. In some embodiments, the molding material 41 includes tetraethoxysilane (TEOS). Other suitable molding materials can be applied, and are not limited herein.

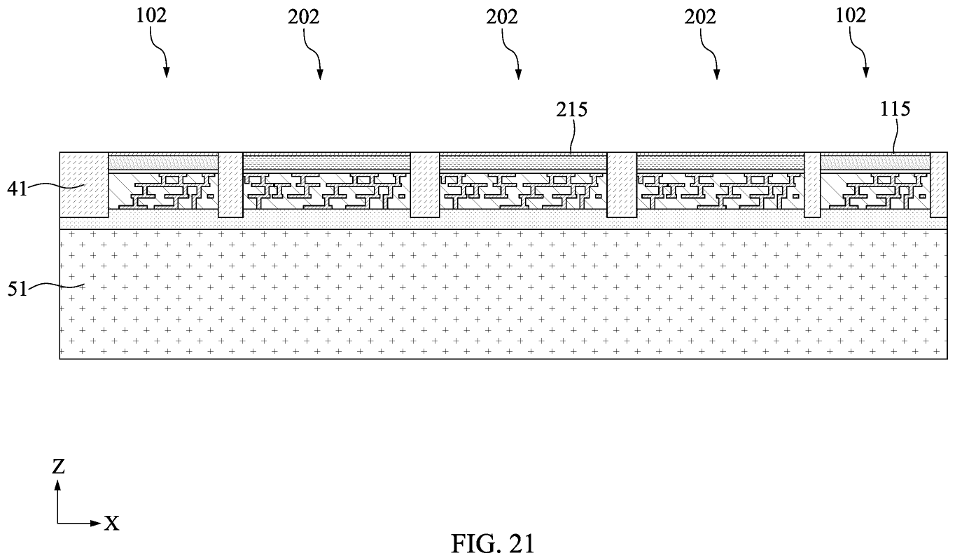

Referring to FIG. 21, a removal operation is performed on the intermediate structure shown in FIG. 19 to further reduce thicknesses of the substrates 111 and 211 until an exposure of the etch stop layers 115 and 215 occurs in accordance with some embodiments of the present disclosure. In some embodiments, a surficial portion of the intermediate structure of FIG. 20 is removed. In some embodiments, a portion of the substrate 111 proximal to the back surface 111B′ is removed, and a portion of the substrate 211 proximal to the back surface 211B′ is removed. The removal operation can include a grinding operation, a polishing operation (e.g., CMP), an etching operation, or a combination thereof. In some embodiments, a grinding operation followed by a polishing operation (e.g., CMP) is performed. In some embodiments, a portion of the molding layer 41 above the back surfaces 111B′ and the back surfaces 211B′ shown in FIG. 20 is removed by an etching operation. In some embodiments, the surficial portions of the substrates 111 and 211 are removed by a polishing operation after the back surfaces 111B′ and 211B′ are exposed.

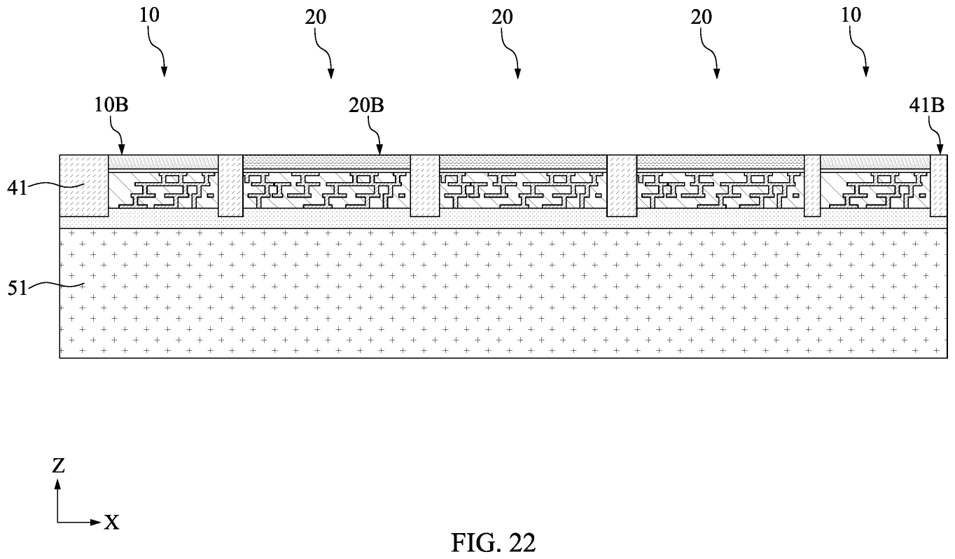

Referring to FIG. 22, the etch stop layers 115 and 215 are removed, and the I/O dies 10 and the processor dies 20 are thereby formed in accordance with some embodiments of the present disclosure. The removal of the etch stop layers 115 and 215 can include a grinding operation, a polishing operation (e.g., CMP), an etching operation, or a combination thereof depending on different applications. A back surface 10B of the substrate 111 defines the back surface of the I/O die 10, and a back surface 20B of the substrate 211 defines the back surface of the processor die 20 after the operations as depicted in FIG. 22. In some embodiments, the back surface 10B of the substrate 111, the back surface 20B of the substrate 211, and a back surface 41B of the molding material 41 are substantially aligned along the X direction. In some embodiments, the back surface 10B of the substrate 111, the back surface 20B of the substrate 211, and a back surface 41B of the molding material 41 are substantially coplanar.

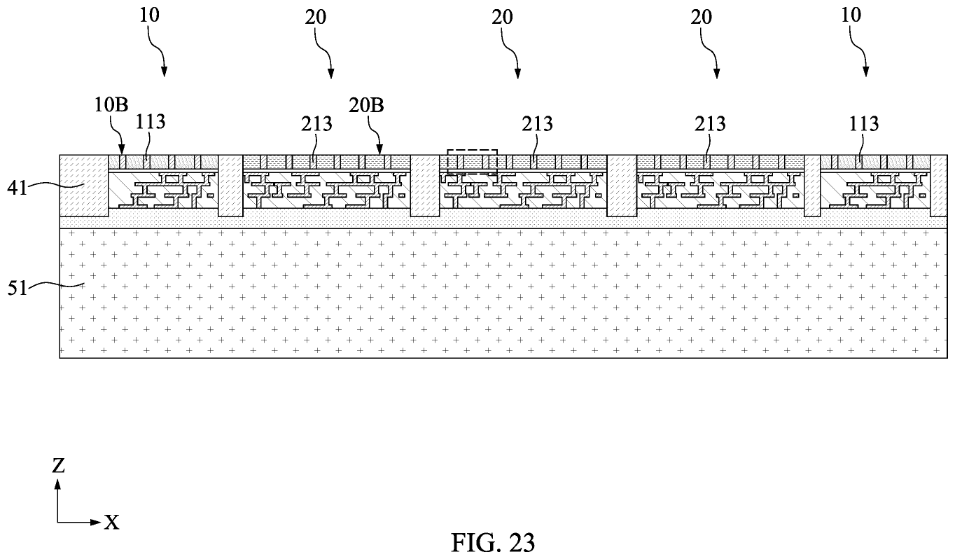

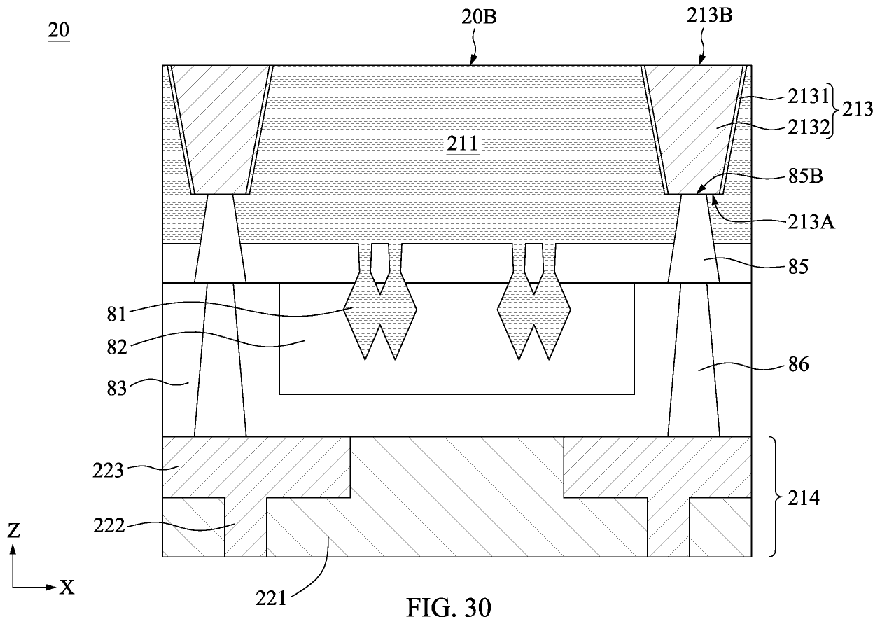

Referring to FIG. 23, a plurality of BSTVs 113 are formed in the substrate 111 of each of the I/O dies 10, and a plurality of BSTVs 213 are formed in the substrate 211 of each of the processor dies 20 in accordance with some embodiments of the present disclosure. In some embodiments, each of the BSTVs 113 and 213 has a top surface substantially aligned with or coplanar with the back surface 10B or 20B of a corresponding substrate 111 or 211. In some embodiments, each of the BSTVs 113 and 213 contacts a conductive feature 85 disposed in the substrate 111 or 211 as shown in FIG. 30. In some embodiments, the conductive feature 85 is referred to as a power rail 85. In some embodiments, a photolithographic process is performed to define positions of the BSTVs 113 and 213 on the back surfaces 10B of the substrate 111 and the back surfaces 20B of the substrate 211.

FIG. 30 is a schematic cross-sectional diagram of a portion of a processor die 20 indicated by a dashed-line rectangle in FIG. 23 in accordance with some embodiments of the present disclosure. In some embodiments, a first surface 213B of the BSTV 213 is exposed through the substrate 211. In some embodiments, the first surface 213B of the BSTV 213 is substantially aligned with the back surface 20B of the substrate 211. The BSTV 213 may include a dielectric layer 2131 and a conductive layer 2132 surrounded by the dielectric layer 2131. In some embodiments, the dielectric layer 2131 is disposed between the conductive layer 2132 and the substrate 211 to electrically isolate the conductive layer 2132 from the substrate 211.

The processor die 20 may further include an active component, which includes a source/drain region 81 and a gate structure 82, a dielectric layer 83, the conductive feature 85 and a contact 86. In some embodiments, the dielectric layer 83 surrounds the active component. In some embodiments, the contact 86 is disposed between the RDL 214 and the substrate 211 to provide electrical connection between the substrate 211 and the RDL 214. In some embodiments, the contact 86 penetrates the dielectric layer 83. In some embodiments, the conductive feature 85 is disposed between the contact 86 and the BSTV 213. In some embodiments, the conductive feature 85 is formed prior to the operations as depicted in FIG. 13. The BSTVs 213 are formed to align with the conductive feature 85 along the Z direction. In some embodiments, for a purpose of alignment, a width of the BSTV 213 is substantially greater than a width of the conductive feature 85 as shown in FIG. 30. In some embodiments, the BSTV 213 extends from the back surface 20B of the substrate 211 along the Z direction and stops at the conductive feature 85. In some embodiments, a second surface 213A opposite to the first surface 213B of the BSTV 213 contacts a bottom surface 85B of the conductive feature 85.

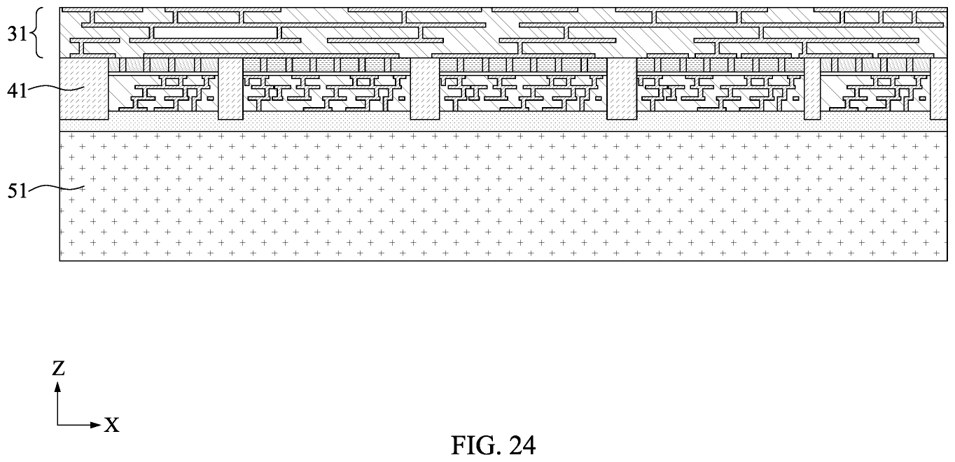

Referring back to FIG. 24, an RDL 31 is formed on the back side 10B of the I/O dies 10, the back side 20B of the processor dies 20 and the molding material 41 in accordance with some embodiments of the present disclosure. In some embodiments, the RDL 31 continuously extends over an entirety of the substrate 51. In some embodiments, the RDL 31 contacts the back surface 10B of the substrate 111, the back surface 20B of the substrate 211, and a back surface 41B of the molding material 41. As described above, the RDL 31 includes a plurality of dielectric layers 311 surrounding a plurality of metal via layers and a plurality of metal line layers. Each metal line layer includes a plurality of metal lines 313, and each metal via layer includes a plurality of metal vias 312. In some embodiments, each of dielectric layers 311 of the RDL 31 is a monolithic structure overlapping an entirety of the substrate 51. The molding material 41 may or may not vertically overlap a metal line 313 depending on a design of electrical connections in the RDL 31. In some embodiments of the semiconductor structure 1 shown in FIG. 1, in order to provide electrical connection between adjacent dies 10 and/or 20 through the RDL 31, at least one metal line 313 extends over (or overlaps) the molding material 41 between the adjacent dies 10 and/or 20. However, in some embodiments of the semiconductor structure 2 or 3 shown in FIGS. 4 and 6, for signal transmission between adjacent dies 10 and/or 20, such signals pass through the RDL 32; thus, in such embodiments, metal lines of the RDL 32 carrying the signal transmission between adjacent dies 10 and/or 20 may be outside an area of vertical projection of the molding material 41. In some embodiments, a portion of the RDL 31 in an area of a vertical projection of the molding material 41 includes only dielectric layers 311 without a metal line 313 or a metal via 312.

In order to form a continuous layer across the entirety of the RDL 31, a mask stitching technique can be applied. For example, the dies 10 and 20 may all have sizes around 26*33 millimeters (mm). However, by stitching different series of masks, a total area of the RDL 31 can be 200*200 mm or even larger, and conductive traces are able to be set across the stitching interface.

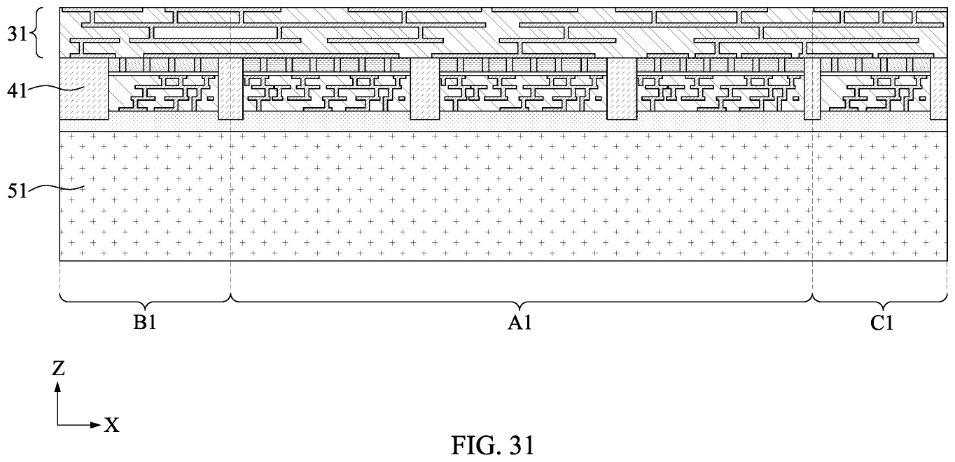

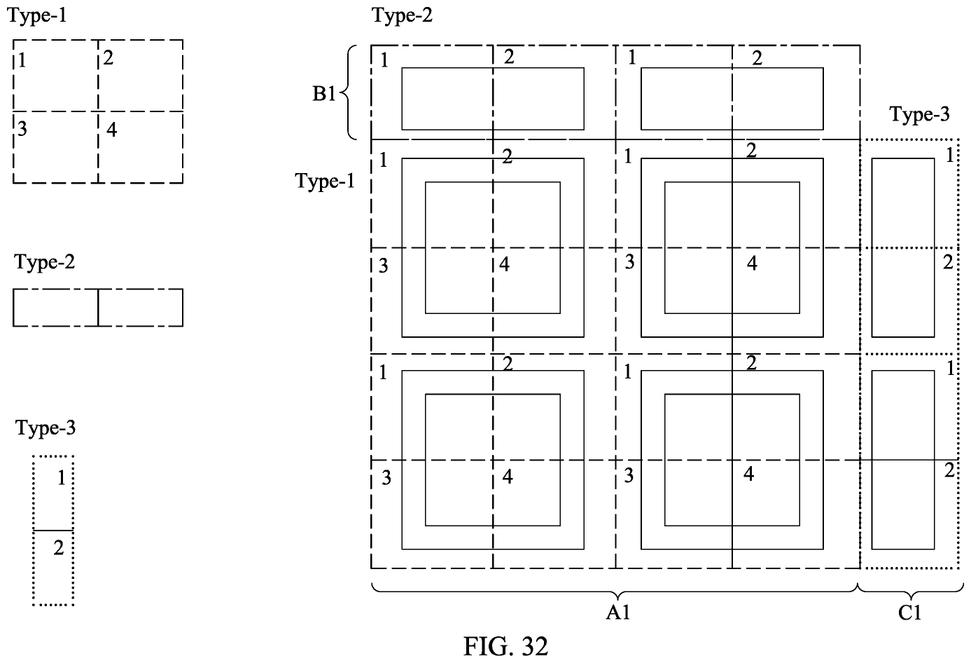

Referring to FIG. 31, the RDL 31 may include different regions A1, B1, and C1, that are formed by utilizing different series of masks. In some embodiments, the dies 20 are all over the region A1 of the RDL 31, some of the dies 10 are over the region B1, and some of the dies 10 are over the region C1. In some embodiments as shown in FIG. 32, three types (or series) of masks are utilized to form the RDL 31. To be more specific, a plurality of first rectangular sub-regions (e.g., 1, 2, 3, and 4 of Type-1) can be formed by utilizing a first type (e.g., Type 1) of masks in the region A1, a plurality of second rectangular sub-regions (e.g., 1 and 2 of Type-2) can be formed by utilizing a second type (e.g., Type-2) of masks in the region B1, and a plurality of third rectangular sub-regions (e.g., 1 and 2 of Type-3) can be formed by utilizing a third type (e.g., Type 3) of masks in the region C1.

In some embodiments, the three types of masks are adopted for lithography in an interactive manner. For example, to pattern a photoresist layer or an inter-layer insulating layer of the RDL 31, a first mask of the first type of masks is applied to expose patterns in the sub-regions 1 of the region A1. Similarly, a second mask, a third mask and a fourth mask of the first type of masks are applied in the sub-regions 2, 3 and 4 of the region A1 respectively. In some embodiments, a first mask of the second type of masks is applied to expose patterns on the sub-regions 1 of the region B1. In some embodiments, a first mask of the third type of masks is applied to expose patterns on the sub-regions 1 of the region C1. Similarly, a second mask of the second type of masks, and a second mask of the third type of masks can be utilized to pattern another photoresist layer or another insulating layer, and so on. After the patterns are exposed on the regions A1, B1, and C1, a solvent may be applied on the photoresist layer or the inter-layer insulating layer to develop the desired patterns of the RDL 31.

It should be noted that three types of masks is for a purpose of illustration, and a number of types of masks is not limited herein. In other embodiments, four types of masks are utilized to form a continuous structure of RDL 31 across an entire semiconductor package as shown in FIGS. 1, 4 and 6. In addition, the mask stitching technique can be applied to form the RDL 32 and the bonding layer 44 shown in FIGS. 4 and 6. Through proper design, patterns of the conductive traces and vias of all the sub-regions 1 in the region A1 may be identical in order to further reduce the cost of mask. However, this is not a limitation to the present disclosure. The same principle applies to other sub-regions 2 to 4 in the region A1, the sub-regions 1 to 2 in the region B1 and the sub-regions 1 to 2 in the region C1.

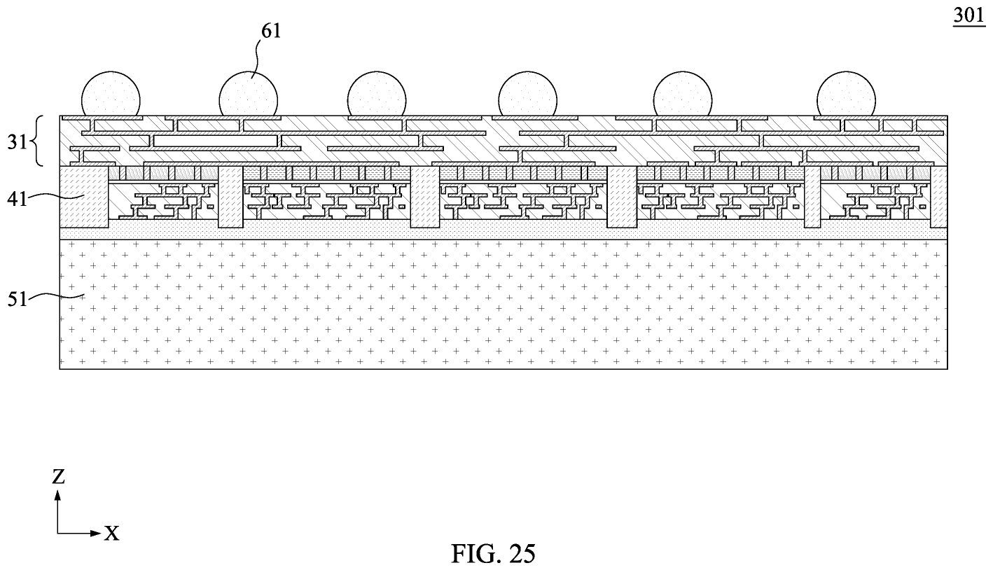

Referring back to FIG. 25, a plurality of connectors 61 are formed on the RDL 31 at a side opposite to the dies 10 and 20 in accordance with some embodiments of the present disclosure. The connectors 61 are electrically connected to a top metal line layer of the RDL 31. In some embodiments, a passivation layer (not shown in FIG. 25) is formed on the RDL 31, and the passivation layer is patterned to expose portions of metal lines of the top metal line layer for electrical connection to the connectors 61. In some embodiments, the connectors 61 are solder bumps. The connectors 61 can be lead (Pb) solders, Pb-free solders, or a tin-silver solder on a copper pillar. In some embodiments, the connectors 61 together are a ball grid array (BGA). In some embodiments, the connectors 61 include bonding pad metals (BPM) and bonding pad vias (BPV). In some embodiments, the connectors 61 are formed by a series of operations, including a seed-layer formation, a plating operation, and a re-flow operation. A semiconductor structure 301 is thereby formed.

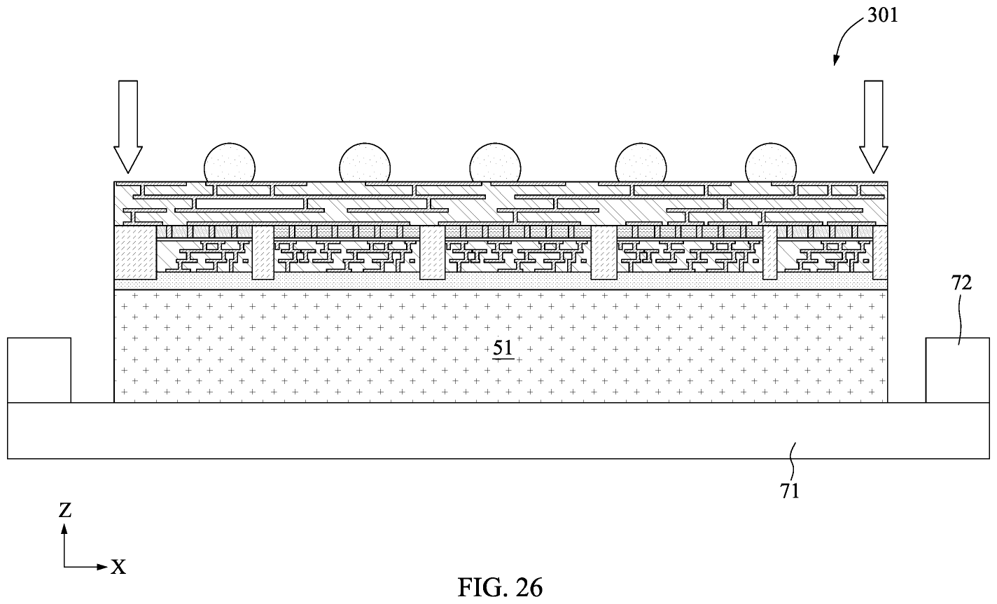

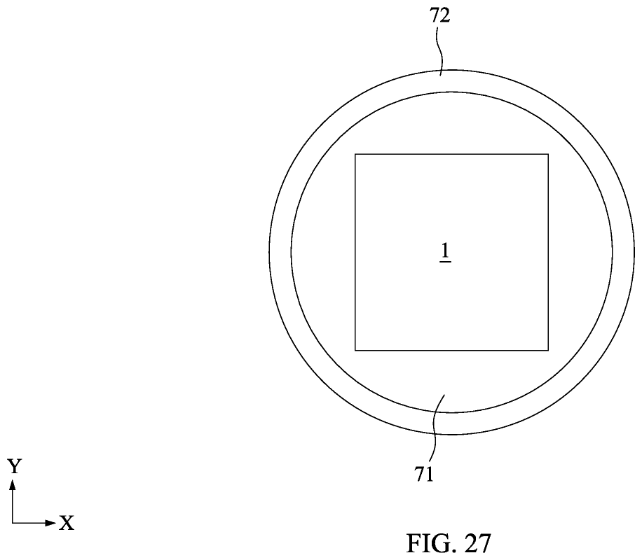

Referring to FIGS. 26 to 27, a sawing operation is performed to saw the semiconductor structure 301 to remove peripheral portions of the semiconductor structure 301 in accordance with some embodiments of the present disclosure. The semiconductor structure 1 is thereby formed. In some embodiments, the semiconductor structure 301 having a circular configuration from a top view (as shown in FIG. 18) is sawed into a rectangular configuration, and the semiconductor structure 1 is thereby formed. In some embodiments, the semiconductor structure 301 shown in FIG. 25 is mounted on a frame 72 and attached to a dicing tape 71 prior to the dicing operation. The semiconductor structure 301 is then sawed as shown in FIG. 26. The semiconductor structure 301 can be considered as an intermediate structure of the semiconductor structure 1, wherein FIG. 27 is a schematic top view of the semiconductor structure 1 on the dicing tape 71 after the sawing operation.

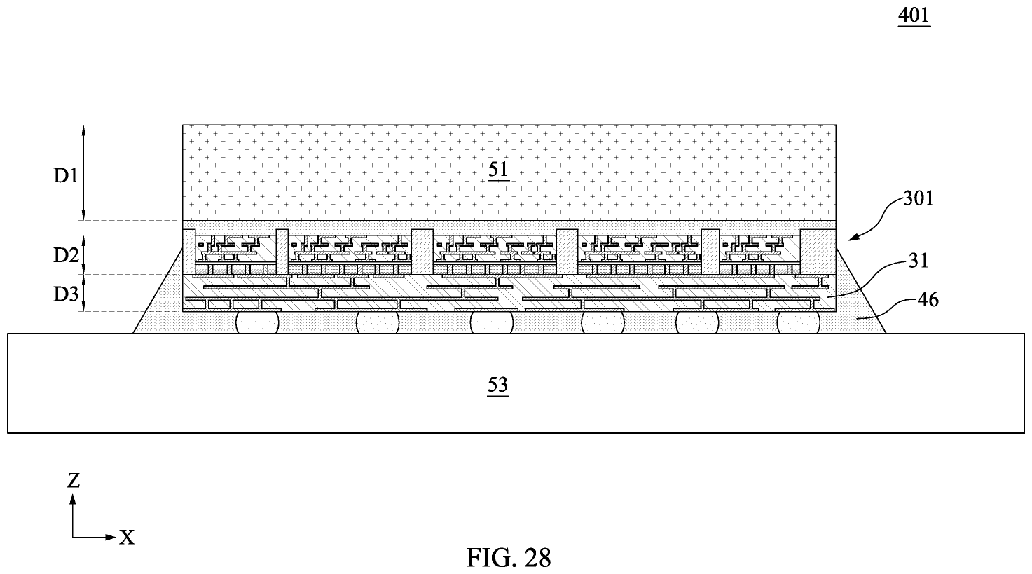

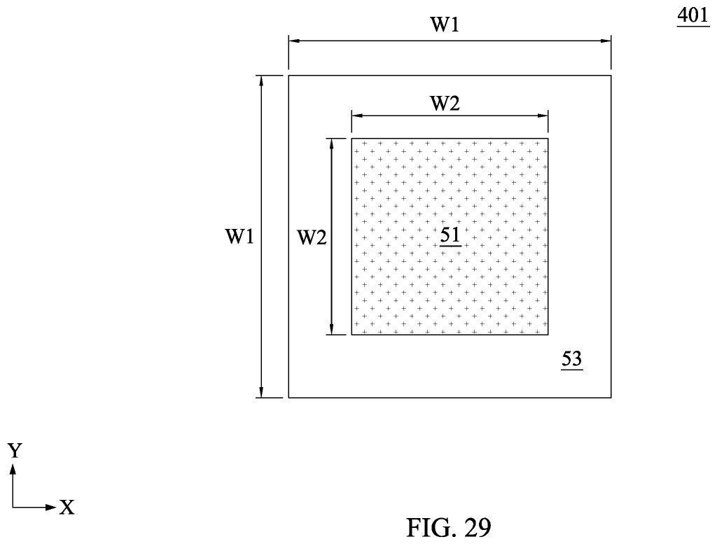

The semiconductor structure 1 can be bonded to a substrate 53 as shown in FIG. 28, and a semiconductor structure 401 is thereby formed. In some embodiments, the I/O dies 10 and the processor dies 20 are electrically connected to the substrate 53 through the connectors 61. In some embodiments, the substrate 53 is a printed circuit board (PCB). In some embodiments, a molding material 46 is disposed between the semiconductor structure 301 and the substrate 53. In some embodiments, the molding material 46 surrounds sidewalls of the semiconductor structure 301. A total thickness of the semiconductor structure 301 can be controlled according to a specification of a device, a required transmission efficiency, and a circuit design. In some embodiments, a thickness of the substrate 51 can be about 775 μm so as to provide sufficient support strength. In some embodiments, a thickness of an I/O die 10 or a processor die 20 can be about 20 μm so as to optimize a density of dies in the semiconductor structure 1. In some embodiments, a thickness of the RDL 31 can be approximately equal to or less than 20 μm. A top view of the semiconductor structure 401 can be as shown in FIG. 29 in accordance with some embodiments of the present disclosure. In some embodiments, the substrate 53 has a square configuration from a top view, and a width W1 of the substrate 53 is about 500 millimeters (mm). In some embodiments, the substrate 51 has a square configuration from a top view, and a width W2 of the substrate 51 is about 200 mm. However, the present disclosure is not limited thereto.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods and steps.

What is claimed is:

1. A semiconductor structure comprising:
a first die, comprising:
a first substrate, having a first active area at a front surface of the first substrate;
a first redistribution layer (RDL), disposed over the front surface of the first substrate; and
a first back-side through via (BSTV), extending from a back surface of the first substrate toward the front surface of the first substrate;
a second die, disposed adjacent to the first die, and separated from the first die by a molding material, wherein the second die comprises:
a second substrate, having a second active area at a front surface of the second substrate;
a second RDL, disposed over the front surface of the second substrate; and
a second BSTV, extending from a back surface of the second substrate toward the front surface of the second substrate; and
a third RDL, continuously disposed over the back surfaces of the first substrate and the second substrate, and electrically connected to the first RDL through the first BSTV and to the second RDL through the second BSTV.

2. The semiconductor structure of claim 1, further comprising:
a plurality of connectors, disposed on the third RDL opposite to the first die and the second die, wherein the connectors are electrically connected to the first die through the first BSTV and to the second die through the second BSTV for power supply to the first die and the second die.

3. The semiconductor structure of claim 2, wherein the first die includes a plurality of first BSTVs, and each of the first BSTVs in a central region of the first die are electrically coupled to the connector through the third RDL.

4. The semiconductor structure of claim 1, wherein the first die is one of a plurality of input/output (I/O) dies configured to receive an I/O signal from the third RDL through the first BSTV, or to transmit an I/O signal to the third RDL through the first BSTV, wherein the first BSTV is in a peripheral region of the first die.

5. The semiconductor structure of claim 4, wherein the second die is one of a plurality of processor dies configured to transmit or process a die-to-die signal between the processor dies through the second BSTV, wherein the second BSTV is in a peripheral region of the second die.

6. The semiconductor structure of claim 1, wherein the third RDL comprises:
a plurality of dielectric layers, each of the dielectric layers being a continuous layer extending over the back surfaces of the first substrate and the second substrate and over a molding material filling a space between the first die and the second die; and
a plurality of metal layers, surrounded by the plurality of dielectric layers.

7. The semiconductor structure of claim 1, further comprising:
a support substrate, disposed over the first RDL and the second RDL, wherein the support substrate is connected to the first die and the second die by a fusion bonding layer.

8. The semiconductor structure of claim 1, further comprising:
a fourth RDL, disposed over the first RDL and the second RDL, wherein the fourth RDL is connected to the first die and the second die by a hybrid bonding layer.

9. The semiconductor structure of claim 7, further comprising:
a support substrate, disposed over the fourth RDL opposite to the third RDL, wherein the fourth RDL is connected to the support substrate by a fusion bonding layer.

10. The semiconductor structure of claim 7, further comprising:
a semiconductor substrate, disposed over the fourth RDL opposite to the third RDL, wherein the semiconductor substrate includes a third active area at a front surface facing the fourth RDL.

11. The semiconductor structure of claim 9, further comprising:
a through molding via (TMV), penetrating the molding material, wherein the TMV electrically connects the third RDL to the fourth RDL for providing a power supply from the third RDL to the semiconductor substrate.

12. The semiconductor structure of claim 1, wherein the first die further comprises a first power rail disposed in the first substrate, and the first BSTV contacts a bottom of the first power rail; and the second die further comprises a second power rail disposed in the second substrate, and the second BSTV contacts a bottom of the second power rail.

13. The semiconductor structure of claim 1, wherein a thickness of the first substrate is substantially equal to a thickness of the second substrate, and the thickness of the first substrate or the second substrate is less than or equal to 1 micron.

14. A method for manufacturing a semiconductor structure, comprising:
forming an etch stop layer in a first substrate proximal to a front surface of the first substrate;
forming an active area at the front surface of the first substrate over the etch stop layer;
forming a first redistribution layer (RDL) over the front surface of the first substrate;
bonding the first RDL to a second substrate;
reducing a thickness of the first substrate from a back surface of the first substrate until an exposure of the etch stop layer occurs;
forming a back-side through via (BSTV) in the first substrate from the back surface of the first substrate; and
forming a second RDL over the back surface of the first substrate, wherein the second RDL electrically connects to the first RDL through the BSTV.

15. The method of claim 14, wherein a distance between the etch stop layer and the front surface of the first substrate is in a range of 0.5 to 2 microns.

16. The method of claim 14, wherein a depth of the BSTV is substantially equal to or less than 1 micron.

17. The method of claim 14, wherein the bonding of the first RDL to the second substrate comprises:
flipping over the first substrate, wherein the front surface of the first substrate faces downward; and
attaching the first substrate to the second substrate prior to the reduction of the thickness of the first substrate.

18. The method of claim 17, wherein the bonding of the first RDL to the second substrate further comprises:
performing a fusion bonding operation to fuse a first dielectric layer over the first RDL to a second dielectric layer over the second substrate.

19. The method of claim 17, wherein the bonding of the first RDL to the second substrate further comprises:
performing a hybrid bonding operation to bond the first substrate to the second substrate through a first hybrid layer of the first RDL and a second hybrid layer over the second substrate.

20. The method of claim 14, wherein the reduction of the thickness of the first substrate comprises:
performing a grinding operation on the back surface of the first substrate, wherein a thickness of the first substrate after the grinding operation is in a range of 10 to 50 microns; and
performing a first polishing operation on the back surface of the first substrate to expose the etch stop layer; and
performing a second polishing operation to remove the etch stop layer prior to the formation of the BSTV.
